(19) United States
(12) Patent Application Publication
(10) Pub. No.: US 2010/0116210 A1
(43) Pub. Date: May 13, 2010

(54) GAS INJECTOR AND FILM DEPOSITION APPARATUS

(75) Inventors: HITOSHI KATO, Oshu-Shi (JP); Yasushi Takeuchi, Oshu-Shi (JP); Manabu Honma, Oshu-Shi (JP); Hiroyuki Kikuchi, Oshu-Shi (JP)

Correspondence Address: IPUSA, P.L.L.C, 1054 31ST STREET, N.W., Suite 400, Washington, DC, 20007, US

(73) Assignee: TOKYO ELECTRON LIMITED, Tokyo (JP)

(21) Appl. No.: 12/615,311

(22) Filed: Nov. 10, 2009

(30) Foreign Application Priority Data
Nov. 10, 2008 (JP) 2008-288136

(51) Int. Cl. C23C 16/00; B05B 1/14

(52) U.S. Cl. 118/730; 239/548

(57) ABSTRACT

An injector body of a gas injector has a gas inlet and a gas passage; plural gas outflow openings disposed on a wall part of the injector body along a longitudinal direction of the injector body; and a guide member that provides a slit-shaped gas discharge opening extending in the longitudinal direction of the injector body on an outer surface of the injector body, and guides gas flowing from the gas outflow openings to the gas discharge opening.

### CROSS-REFERENCE TO RELATED APPLICATION

This application is based upon and claims the benefit of priority of Japanese Patent Application No. 2008-288136, filed on Nov. 10, 2008, the contents of which are incorporated herein by reference in their entirety.

### BACKGROUND OF THE INVENTION

1. Field of the Invention

This invention relates to a gas injector and a film deposition apparatus.

2. Description of the Related Art

As a film deposition method in a semiconductor manufacturing process, a process is known in which, after a first reaction gas is made to be adsorbed on a surface of a semiconductor wafer (simply referred to as a wafer, hereinafter) as a substrate or such in a vacuum atmosphere, a gas to be provided is switched to a second reaction gas, one or more layers of atomic layers or molecular layers are formed from reaction of both first and second reaction gases, this cycle is repeated many times, and thus, these layers are laminated to carry out film deposition on the substrate. This process is called ALD (Atomic Layer Deposition) or MLD (Molecular Layer Deposition) (simply referred to as an ALD method, hereinafter). It is possible to control a film thickness with high precision by controlling the number of cycles to repeat the process until in-plane film property uniformity is satisfactory, and thus, the process is effective in achieving a thinner semiconductor device.

As an apparatus to carry out such a film deposition method, a method has been studied in which a single-wafer film deposition apparatus provided with a gas shower head at the top center of a vacuum chamber is used, reaction gases are provided from the top to the center of a substrate, and un-reacted reaction gases and reaction by-products are ejected from the bottom of the vacuum chamber. This film deposition method may have a problem such that a long time is required for gas replacement by using a purge gas, the number of repeating cycles is large, for example, hundreds of times of repeating cycles may be required, and thus, a processing time is long. Therefore, an apparatus and a method by which the process can be carried out with a higher throughput is in demand.

From the above-mentioned background, Patent Documents 1 through 8 disclose film deposition apparatuses in which plural substrates are disposed in a rotation direction on a turntable in a vacuum chamber, and film deposition is carried out. However, in these film deposition apparatuses, a problem that particles or reaction products adhere to a wafer, a problem that a long purge time is required, a problem that reaction occurs in an unnecessary zone, or such, may be considered.

Patent Document 1: U.S. Pat. No. 7,153,542, FIG. 6(a), FIG. 6(b)

Patent Document 2: Japanese Laid-Open Patent Application No. 2001-254181, FIG. 1, FIG. 2

Patent Document 3: Japanese Patent No. 3144664, FIG. 1, FIG. 2, claim 1

Patent Document 4: Japanese Laid-Open Patent Application No. 4-287912

Patent Document 5: U.S. Pat. No. 6,634,314

Patent Document 6: Japanese Laid-Open Patent Application No. 2007-247066, paragraphs 0023-0025, 0058, FIG. 12 and FIG. 18

Patent Document 7: United States Patent Publication No. 2007-218701

Patent Document 8: United States Patent Publication No. 2007-218702

### SUMMARY OF THE INVENTION

The present invention has been devised in consideration of the above-mentioned situation, and an aspect of the present invention is to provide a configuration to solve the problems disclosed in the Patent Documents 1-8, and also, to solve a problem which may newly occur in a process of solving the above-mentioned problems.

In an aspect of this disclosure, a gas injector has an injector body having a gas inlet and a gas passage; plural gas outflow openings disposed on a wall part of the injector body along a longitudinal direction of the injector body; and a guide member that provides a slit-shaped gas discharge opening extending in the longitudinal direction of the injector body on an outer surface of the injector body, and guides gas flowing from the gas outflow openings to the gas discharge opening.

In another aspect of this disclosure, a film deposition apparatus, which forms a thin film of reaction products laminated on a surface of a substrate by repeating a cycle of providing to the surface of the substrate at least two reaction gases in sequence which react to each other in a vacuum chamber, has a turntable in the vacuum chamber; a substrate placing area on the turntable for placing the substrate; a first reaction gas providing part that provides a first reaction gas to a side of the turntable on which the substrate placing area is provided and a second reaction gas providing part that provides a second reaction gas to the side of the turntable, the first and second reaction gas providing parts being apart from one another in a rotation direction of the turntable; a separating zone that separates an atmosphere of a first processing zone for providing the first reaction gas and an atmosphere of a second processing zone for providing the second reaction gas, the separating zone being located between the first processing zone and the second processing zone in the rotation direction of the turntable, the separating zone having a separating gas providing part that provides a separating gas; and an evacuation opening that evacuates the vacuum chamber. At least one of the first and second reaction providing parts is the above-mentioned gas injector, the gas injector extends across the rotation direction of the turntable, and the gas discharge opening of the gas injector faces toward the turntable.

Other aspects, features and advantages of this disclosure will be apparent from the following detailed description when read in conjunction with the accompanying drawings.

### BRIEF DESCRIPTION OF THE DRAWINGS

FIG. 1 is a vertical cross-sectional view of a film deposition apparatus in one mode for carrying out the embodiments of the present invention taken along a I-I′ line of FIG. 3;

FIG. 2 is a perspective view depicting a general configuration of the inside of the film deposition apparatus;

FIG. 3 is a horizontal cross-sectional view of the film deposition apparatus;

FIGS. 4A and 4B are vertical cross-sectional views of the film deposition apparatus depicting processing zones and separating zones;

FIG. 5 is a partial vertical cross-sectional view of the film deposition apparatus depicting the separating zone;

FIG. 6 depicts a manner of flowing a separating gas or a purge gas;

FIG. 7 is a partial perspective view depicting a gas injector provided in the film deposition apparatus;

FIG. 8 is a vertical cross-sectional view of the gas injector;

FIG. 9 is a perspective view of the gas injector;

FIGS. 10A and 10B are a side view and a bottom view of the gas injector;

FIG. 11 illustrates a manner of a first reaction gas and a second reaction gas being separated by the separating gas and ejected;

FIG. 12 is a vertical cross-sectional side view of a gas injector in another example;

FIG. 13 is a perspective view of the gas injector in the other example;

FIGS. 14A and 14B illustrate an example of a size of projection parts used in the separating zones;

FIG. 15 is a horizontal cross-sectional view of a film deposition apparatus in another mode for carrying out the embodiments of the present invention;

FIG. 16 is a horizontal cross-sectional view of a film deposition apparatus in further another mode for carrying out the embodiments of the present invention;

FIG. 17 is a vertical cross-sectional view of a film deposition apparatus in further another mode for carrying out the embodiments of the present invention;

FIG. 18 is a general plan view of one example of a substrate processing system using a film deposition apparatus according to a mode for carrying out the embodiments of the present invention;

FIG. 19 is a general plan view of a configuration of a simulation model for film deposition apparatuses in embodiments 1 and 2 and comparison examples 1 and 2;

FIGS. 20A, 20B, 20C and 20D illustrate configurations of reaction gas providing parts in the embodiments 1 and 2 and comparison examples 1 and 2, respectively; and

FIG. 21 illustrates simulation results of the embodiments 1 and 2 and comparison examples 1 and 2.

### DETAILED DESCRIPTION OF PREFERRED EMBODIMENTS

Modes for carrying out the embodiments of the present invention relate to the art of forming a thin film by laminating layers of reaction products as a result of repeating many times a providing cycle that provides in sequence at least two reaction gases that react to each other to a surface of a substrate.

Before describing the modes for carrying out the embodiments of the present invention, a film deposition apparatus in a reference example will now be described for the purpose of comparison. The film deposition apparatus in the reference example is a turntable-type film deposition apparatus that may solve the problems disclosed by Patent Documents 1-8.

In the film deposition apparatus in the reference example, many gas outflow openings are provided on a bottom surface of a long cylindrical gas nozzle along a longitudinal direction of the gas nozzle that extends along a direction crossing a rotation direction of a turntable. A reaction gas is discharged onto a surface of a wafer placed on a substrate placing area on the turntable that passes under the gas nozzle as the turntable turns. For example, two gas nozzles are used for continuously providing two reaction gases, the turntable turns, and thus, these reaction gases are alternately provided onto the surface of the wafer. Then, for example, a film deposition process experiment was carried out to form a silicon oxide film on the surface of the wafer. As a result, a phenomenon was observed in which a film thickness of the thus-formed film changed to undulate along the longitudinal direction of the gas nozzle. Observing the manner of the change in the film thickness, the change in the film thickness was observed such that, the film was thick at areas passing under the gas outflow openings, and was thin at other areas. That is, it was observed that the gas outflow openings provided on the gas nozzle were reflected as such differences in film thickness of the silicon oxide film on the surface of the wafer. Such a phenomenon will be referred to as “undulation”, hereinafter.

Generally speaking, the ALD method is a film deposition method that uses adsorption of reaction gas atoms or molecules onto a surface of a wafer, and thus, it is known that film thickness uniformity is satisfactory. A cause of occurrence of the above-mentioned phenomenon of undulation in the turntable-type film deposition apparatus, although the film deposition method is such that film thickness uniformity is satisfactory, is believed to be as follows. That is, the reaction gas is directly made to blow on the surface of the wafer from the gas outflow openings scattered on the bottom surface of the gas nozzle, and there may be a case where the turntable turns to pass under the gas nozzle at a very high rotational speed such as hundreds of rpm, and so forth. Thereby, before adsorption of the reaction gases reach equilibrium, the wafer moves away from the gas outflow openings, and thus, amounts of the reaction gases adsorbed on the wafer vary between areas immediately below the gas outflow openings and the other areas.

In order to avoid the undulation phenomenon, it is necessary to uniformly provide the reaction gas along a longitudinal direction of the nozzle. For this purpose, a slit may be provided that extends along the longitudinal direction of the nozzle, instead of the gas outflow openings. However, the slit may have a large flow rate when the reaction gas passes therethrough, in comparison to the gas outflow openings. Therefore, when the reaction gas is provided to the base end of the gas nozzle, a difference in a discharged gas amount onto the wafer may be large between the base end at which a pressure is high and the extending end at which a pressure is low. As a result, it may be difficult to provide the reaction gas with a uniform concentration. In order to reduce the difference in the discharged gas amount between the base end and the extending end, the gas nozzle having a large pipe diameter may be used. However, in this case, a space required for accommodating the gas nozzle increases accordingly, which may result in an increase in a size of the vacuum chamber and thus, in an increase in a size of the film deposition apparatus.

According to modes for carrying out the present invention, by providing a configuration described below, a gas discharged from gas outflow openings provided on a wall part of an injector body included in a gas injector is guided by a guide member, and the gas is provided via a slit-shaped gas discharge opening extending along a longitudinal direction of the injector body. As a result, it is possible to disperse the gas in the direction in which the gas discharge opening extends when the gas is guided by the guide member. Therefore, for example, in a process in which the gas is made to be adsorbed on a surface of a substrate placed on a placing area as a result of the gas being provided onto the substrate by the gas injector, it is possible to provide the gas having a concentration that is uniform in the direction in which the injector body extends. Thereby, in comparison to a case where a gas injector is used in such a way that a gas discharged from gas outflow openings provided on a wall part of an injector body is directly made to blow on a substrate, it is possible to avoid occurrence of such a problem that a gas amount adsorbed on the substrate is different between positions at which the gas outflow openings are provided and the other areas.

Therefore, according to modes for carrying out the embodiments of the present invention, it is possible to provide a gas injector that can provide a gas having a concentration that is uniform along a longitudinal direction of an injector body, and to provide a film deposition apparatus provided with the gas injector.

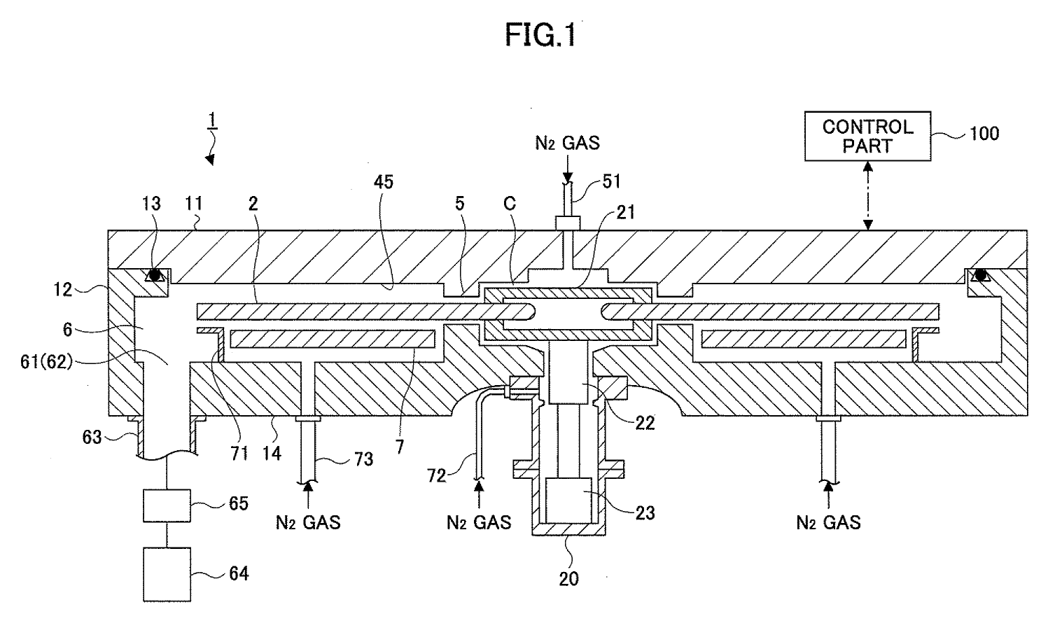

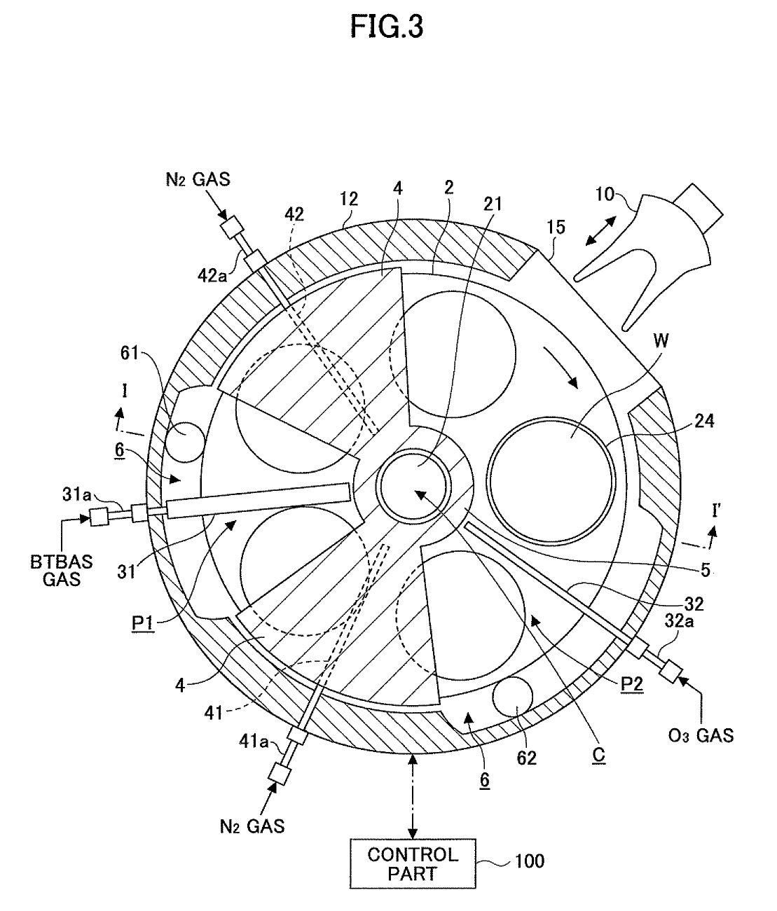

A film deposition apparatus according to a mode for carrying out the embodiments of the present invention includes a flat vacuum chamber 1 having an approximately circular plan view shape, and a turntable 2 provided in the vacuum chamber 1, the turntable 2 having a rotation center at the center of the vacuum chamber 1, as depicted in FIG. 1 (cross-sectional view taken along a I-I′ line of FIG. 3). The vacuum chamber 1 is configured such that a top plate 11 can be separated from a chamber body 12. The top plate 11 is pressed to the side of the chamber body 12 via a sealing member, for example, an O-ring 13, provided on a top surface of the chamber body 12, because of a reduced pressure inside, so that airtightness of the vacuum chamber 1 is maintained. In order to separate the top plate 11 from the chamber body 12, a driving mechanism not depicted is used to lift the top plate 11.

The turntable 2 is fixed to a cylindrical core part 21 at a center part, and the core part 21 is fixed to a top end of a rotation shaft 22 extending vertically. The rotation shaft 22 passes through a bottom part 14 of the vacuum chamber 1, and a bottom end of the rotation shaft 22 is mounted on a driving part 23 which rotates the rotation shaft 22 around a vertical axis, i.e., clockwise in this example. The rotation shaft 22 and the driving part 23 are held in a tubular case member 20 having an opening at the top. A flange part provided on a top surface of the case member 20 is mounted on a bottom surface of the bottom part 14 of the vacuum chamber 1 in an airtight manner, and airtightness between an inside atmosphere and an outside atmosphere of the case member 20 is maintained.

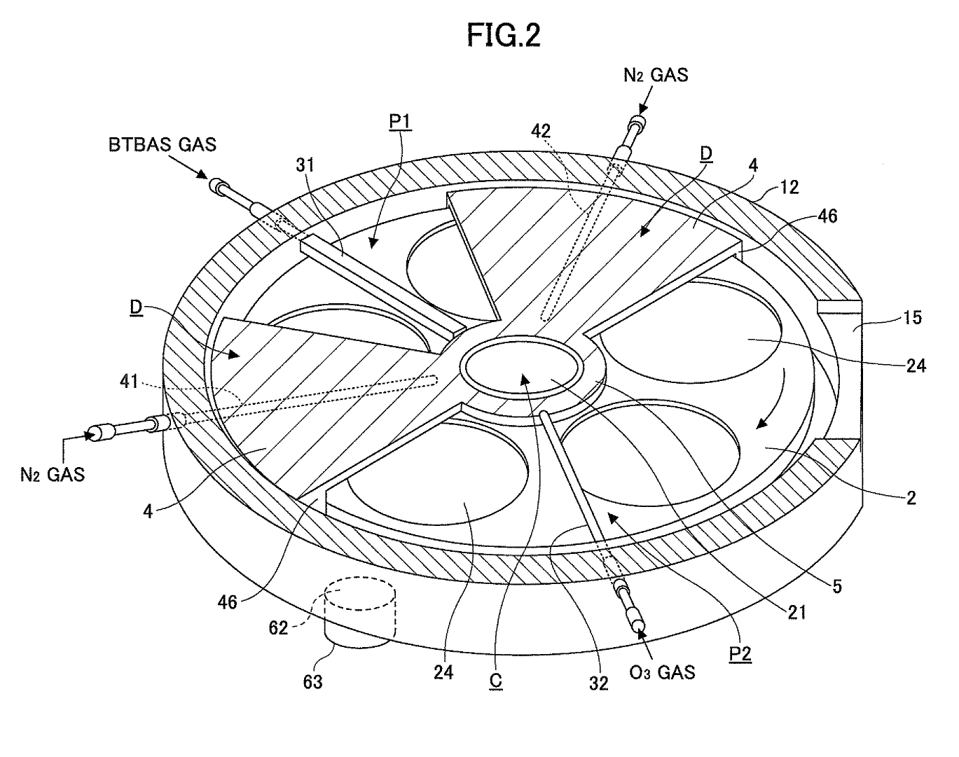

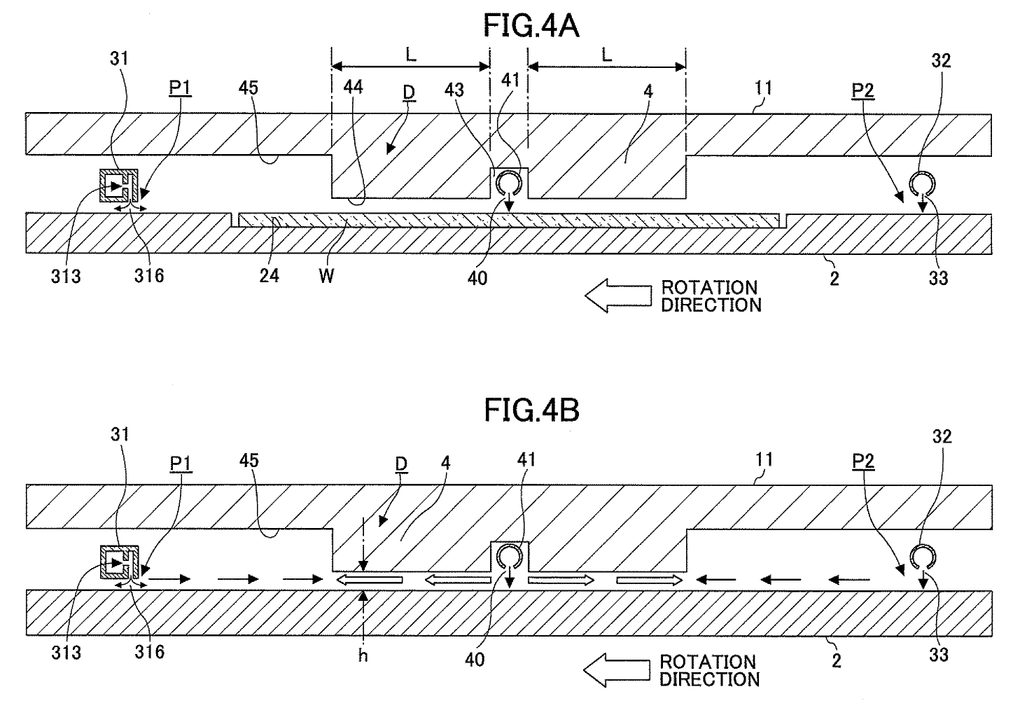

On a surface part of the turntable 2, as depicted in FIGS. 2 and 3, circular recession parts 24 are provided for placing plural, for example, five wafers W which are substrates, along a rotation direction (circumferential direction). It is noted that a wafer W is depicted only in one of the single recession parts 24 in FIG. 3 for the purpose of convenience for description. However, this example should not be so limited, and it is possible to place five wafers W on the five recession parts 24, respectively. FIGS. 4A and 4B depict exploded views obtained from the turntable 2 being cut concentrically along a circle, and then, being expanded horizontally. Each recession part 24 has a diameter slightly larger than a diameter of the wafer W, for example, by 4 mm. Each recession part 24 has a depth equal to a thickness of the wafer W. Accordingly, when the wafer W is placed in the recession part 24, a surface of the wafer W is flush with a surface (area other than an area in which the wafer is placed) of the turntable 2. If a difference between the surface of the wafer W and the surface of the turntable 2 is large, a pressure difference may occur at the step part, and therefore, it is preferable that the surface of the wafer W be flush with the surface of the turntable 2, from a viewpoint of achieving film thickness in-plane uniformity. To make the surface of the wafer W flush with the surface of the turntable 2 means the wafer W and the surface of the turntable 2 have the same height, or, a difference between the surfaces falls within 5 mm. It is preferable to reduce the difference between the surfaces to zero as much as possible depending on accuracy of finishing or such. On a bottom surface of each recession part 24, through holes (not depicted) are provided through which, for example, three lifting pins (described later) pass for supporting a rear side of the wafer W and moving the wafer W up and down.

The recession parts 24 are provided for the purpose of positioning the wafers W and preventing the wafers W from being removed because of centrifugal force caused by rotation of the turntable 2. The recession parts 24 are portions corresponding to substrate placing areas. However, the substrate placing area is not limited to such a recession part, and instead, for example, may be plural guide members that guide a circumferential edge of the wafer W provided along a circumferential direction of the wafer W on the surface of the turntable 2. Alternatively, in a case where a chucking mechanism such as an electrostatic chuck is provided to the side of the turntable 2, and the wafer W is attracted thereby to the surface of the turntable 2, an area to which the wafer W is placed as a result of being thus attracted is the substrate placing area.

As depicted in FIGS. 2 and 3, in the vacuum chamber 1, a gas injector 31, a reaction gas nozzle 32 and two separating gas nozzles 41 and 42 extend radially from a center part of the vacuum chamber 1 apart from each other in a circumferential direction of the vacuum chamber 2 (the rotation direction of the turntable 2) at positions facing passing areas of the recession parts 24 on the turntable 2. As a result, the gas injector 31 is disposed to extend in a direction across the rotation direction, i.e., a moving path of the turntable 2. The gas injector 31, reaction gas nozzle 32 and the separating gas nozzles 41 and 42 are mounted on, for example, a side circumferential wall of the vacuum chamber 1, and gas providing ports 31a, 32a, 41a and 42a, which are base end parts, pass through the side circumferential wall.

The gas injector 31, reaction gas nozzle 32, and the separating gas nozzles 41 and 42 are, in the example depicted, introduced to the inside of the vacuum chamber 1 from the side circumferential wall of the vacuum chamber 1. However, instead, they may be introduced from an annular protrusion part 5 described later. In this case, L-shaped conduits are provided that have openings on an outer circumferential surface of the protrusion part 5; and on an outer surface of the top plate 11, the gas injector 31, reaction nozzle 32 and separating gas nozzles 41 and 42 are connected to the openings on one side of the L-shaped conduits, and the gas providing ports 31a, 32a, 41a and 42a are connected to the other openings of the L-shaped conduits outside the vacuum chamber 1.

The gas injector 31 and reaction gas nozzle 32 are connected to a gas providing source of a BTBAS (a bis (tertiary-butylamino) silane (BTBAS) gas (not depicted) that is a first reaction gas, and a gas source of a O₃ (ozone) gas (not depicted) that is a second reaction gas, respectively. Each of the separating gas nozzles 41 and 42 is connected to a gas source (not depicted) of a N₂ gas (nitrogen gas) that is a separating gas. The gas injector 31 and the reaction gas nozzle 32 are also connected to the gas source of the N₂ gas, and provide the N₂ gas as a pressure adjusting gas to processing zones P1 and P2, respectively, when operation of the film deposition apparatus is started. In this example, the gas injector 31, reaction gas nozzle 32 and separating gas nozzles 41 and 42 are arranged in the stated order clockwise.

As depicted in FIGS. 4A and 4B, gas discharge openings 33 for discharging the O₃ gas are arranged apart from each other in a longitudinal direction on the reaction gas nozzle 32 on a lower side. Further, discharge openings 40 for discharging the separating gas are arranged apart from each other in longitudinal directions on the corresponding separating gas nozzles 41 and 42 on a lower side. A detailed configuration of the gas injector 31 that provides the BTBAS gas will be described later. The gas injector 31 and reaction gas nozzle 32 correspond to a first reaction gas providing part and a second reaction gas providing part, respectively, and respective lower zones are the first processing zone P1 for causing the BTBAS gas to adsorb on the wafer W, and the second processing zone P2 for causing the O₃ gas to adsorb on the wafer W.

The separating gas nozzles 41 and 42 provide the N₂ gas for the purpose of providing separating zones D that separate respective atmospheres of the first processing zone P1 and the second processing zone P2. On the top plate 11 of the vacuum chamber 1 in the separating zones D, projection parts 4 are provided as depicted in FIGS. 2-4B. Each of the projection parts 4 has a sectorial plan view shape, projects downward, has the center positioned at the rotation center of the turntable 2, and divides in a circumferential direction a circle drawn along the vicinity of an inner circumferential wall. The separating gas nozzles 41 and 42 are held in grooves 43 provided to extend in radial directions of the circle at centers in the circumferential direction of the projection parts 4. That is, distances from central axes of the separating gas nozzle 41 (42) to both edges (upstream edges and downstream edges in the rotating direction) of the sectors of the projection parts 4 are set to have equal lengths.

It is noted that, in the mode for carrying out the embodiments of the present invention, the grooves 43 are provided to divide the projection parts 4 into two equal parts. However, in another mode for carrying out the embodiments of the present invention, the grooves 43 may be provided such that upstream sides of the projection parts 4 from the grooves 43 in the rotation direction of the turntable 2 are wider than downstream sides in the rotation direction, for example.

Therefore, on both sides in the circumferential direction of the separating gas nozzles 41 and 43, flat and low ceiling surfaces 44 (first ceiling surfaces) exist that are bottom surfaces of the projection parts 4. On both sides of the ceiling surfaces 44 in the circumferential direction, ceiling surfaces 45 (second ceiling surfaces) that are higher than the ceiling surfaces 44 exist. A role of the projection parts 4 is to provide separating spaces that are narrow spaces for the purposed of avoiding infiltration of the first reaction gas and the second reaction gas in between the projection parts 4 and the turntable 2, and preventing these reaction gases from mixing together.

That is, as to the separating gas nozzle 41 for example, the separating gas nozzle 41 avoids infiltration of the O₃ gas from the upstream side in the rotation direction of the turntable 2, and avoids infiltration of the BTBAS gas from the downstream side in the rotation direction of the turntable 2. “Avoiding infiltration of the gas” means that the N₂ gas that is the separating gas discharged from the separating gas nozzle 41 diffuses between the first ceiling surface 44 and the top surface of the turntable 2, and, in this example, blows into a space under the second ceiling surfaces 45 adjacent to the first ceiling surface 44, whereby infiltration of the gas from the adjacent spaces is avoided. Further, “avoiding infiltration of the gas” not only means completely avoiding infiltration of the gas into the spaces under the projection parts 4 from the adjacent spaces, but also means a case where, although the gas irrupts slightly, it can be ensured that the O₃ gas and the BTBAS gas irrupting from respective sides do not mix together in the spaces under the projection parts 4. By having such a function, the separating zones D can take the role of separating the atmosphere of the first processing zone P1 and the atmosphere of the second processing zone P2. Accordingly, a degree of narrowness of the narrow spaces is such that a pressure difference between the narrow spaces (the spaces under the projection parts 4) and zones adjacent to the spaces (in this example, the spaces under the second ceiling surfaces 45) is set to have a magnitude such that the function of “avoiding infiltration of the gas” can be ensured. A specific size of the narrow spaces depends on areas of the projection parts 4 and so forth. It is noted that, needless to say, the gas having been adsorbed on the wafer W can pass the separating zones D, and “avoiding infiltration of the gas” means avoiding infiltration of the gas that is in a gas phase.

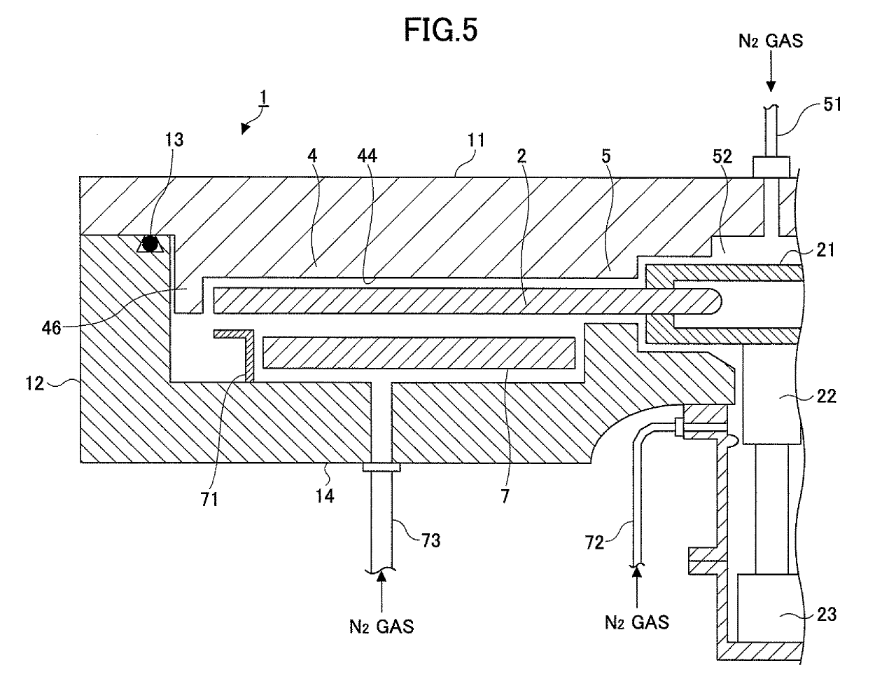

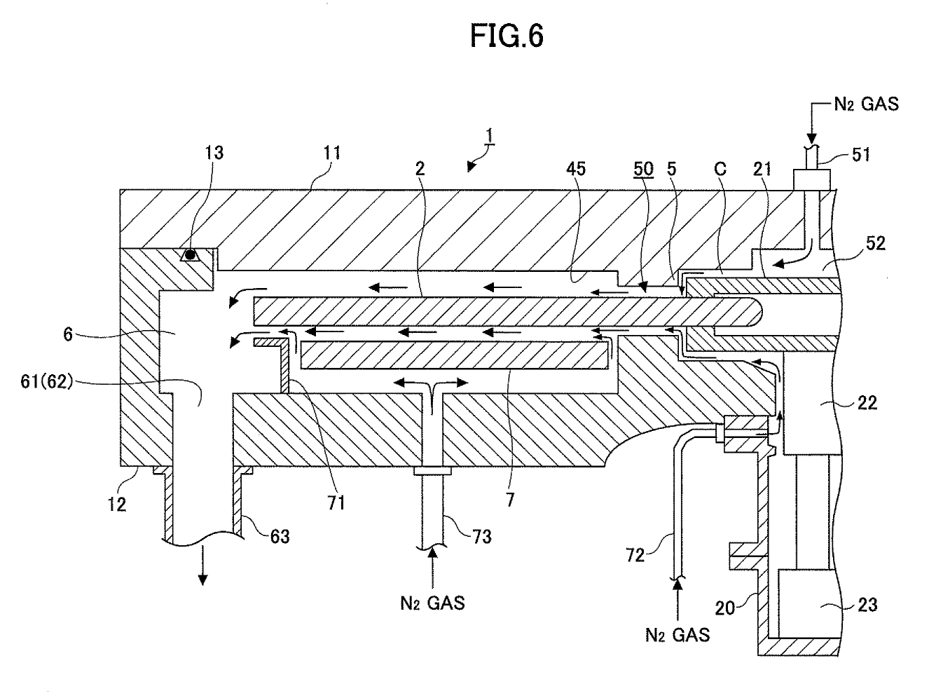

As depicted in FIGS. 5 and 6, the protrusion part 5 is provided to face onto a portion of the turntable 2 that is on the outside of the core part 21, along an outer circumferential surface of the core part 21. The protrusion part 5 is provided to continue from portions of the projection parts 4 that are on the side of the rotation center. A bottom surface of the protrusion part 5 has the same height as those of the bottom surfaces (the ceiling surfaces 44) of the projection parts 4. FIGS. 2 and 3 are views taken from cutting horizontally the top plate 11 at a position higher than the separating gas nozzles 41 and 42 and lower than the above-mentioned ceiling surfaces 45. It is noted that, the protrusion part 5 and the projection parts 4 should not necessarily be one piece, but may be separate pieces.

A specific method for producing a combined structure of the projection part 4 and the separating gas nozzle 41 (42) is not limited to a method in which the groove 43 is formed at the center of a single sectorial plate for the projection part 4, and the separating gas nozzle 41 (42) is placed in the groove 43. Another method may be applied in which two sectorial plates are used, and are fixed to the bottom surface of the top plate body such as being bolted down or so at both side positions of the separating gas nozzle 41 (42), for example.

In this example, the discharge openings 40 each having a bore diameter of 0.5 mm facing just downward are disposed along the longitudinal direction of the separating gas nozzle 41 (42), for example, at intervals of 10 mm, on the separating gas nozzle 41 (42). Also as for the reaction gas nozzle 32, the discharge openings 33 each having a bore diameter of 0.5 mm facing just downward are disposed along the longitudinal direction of the reaction gas nozzle 32, for example, at intervals of 10 mm.

In this example, the wafer W having a diameter of 300 mm is used as a to-be-processed substrate, and in this case, each projection part 4 has a circumferential length (an arc length of a concentric circle of the turntable 2) of 146 mm, for example, at a boundary portion between the projection parts 4 and the protrusion part 5 apart from the rotation center by 140 mm as described later, and has a circumferential length of 502 mm, for example, at the outermost portion of the wafer W placing areas (reception areas 24). It is noted that, as depicted in FIG. 4A, a circumferential length L of the projection part 4 located on both sides from corresponding edges of the separating gas nozzle 41 (42) at the outermost portion is 246 mm.

Further, as depicted in FIG. 4B, a height h of the bottom surface of the projection part 4, i.e., the ceiling surface 44 from the surface of the turntable 2 falls, for example, in a range from 0.5 mm through 10 mm, and may preferably be approximately 4 mm. In this case, the rotational speed of the turntable 2 is set to fall, for example, in a range from 1 rpm through 500 rpm. In order to ensure the separating function of the separating zone D, a size of the projection part 4, and/or the height h between the bottom surface (the first ceiling surface 44) of the projection part 4 and the surface of the turntable 2 are set, depending on an operating range of the rotational speed of the turntable 2, for example, based on an experiment, or such. It is noted that, as the separating gas, not only N₂ gas, but also an inert gas such as Ar gas may be used. Further, not only inert gases, but also hydrogen gas or such may be used. As to a sort of gas, it is not necessary to limit the sort of gas as long as the separating gas does not affect the film deposition process.

On the bottom surface of the top plate 11 of the vacuum chamber 1, i.e., on a ceiling surface of the wafer placing areas (the recession areas 24), there are the first ceiling surfaces 44 and the second ceiling surfaces 45 higher than the first ceiling surfaces 44 in the circumferential direction, as mentioned above. FIG. 1 is a vertical cross-sectional view for a zone in which the high ceiling surfaces 45 are provided. FIG. 5 is a vertical cross-sectional view for a zone in which the low ceiling surfaces 44 are provided. A peripheral part (a portion on the outer edge side of the vacuum chamber 1) of the sectorial projection part 4 is bent to be L-shaped to form a bent part 46 that faces onto the outer end surface of the turntable 2, as depicted in FIGS. 2 and 5. The sectorial projection part 4 is provided in the top plate 11 and the top plate 11 is removable from the chamber body 12. Therefore, slight spaces exist between the outer end surface of the turntable 2 and an inner circumferential surface of the bent part 46 and between an outer circumferential surface of the bent part 46 and the inner circumferential surface of the chamber body 12. Therefore, the bent part 46 is provided for the purpose of avoiding infiltration of the reaction gases from both sides to prevent the reaction gases from mixing together, the same as the projection part 4. Therefore, the space between the inner circumferential surface of the bent part 46 and the outer end surface of the turntable 2 is set to have a size, for example, equal to or similar to the height h of the ceiling surface 44 with respect to the surface of the turntable 2. That is, in this example, when viewed from a zone on the side of the surface of the turntable 2, the inner circumferential surface of the bent part 46 is included in an inner circumferential wall of the vacuum chamber 1.

The inner circumferential wall of the chamber body 12 has a vertical surface approaching the outer circumferential surface of the bent part 46 in the separating zone D as depicted in FIG. 5. However, in a portion other than the separating zone D, as depicted in FIG. 1, the inner circumferential wall of the chamber body 12 is cut out to be concave to the outside to have a rectangular shape in a vertical cross-sectional view, from a portion facing onto the outer end surface of the turntable 2 through a bottom surface part 14, for example. A space between the circumferential edge of the turntable 2 and the inner circumferential wall of the chamber body 12 in the caved portion communicates with each of the first processing zone P1 and the second processing zone P2, and is used to eject the reaction gases provided to the respective processing zones P1 and P2. The space is referred to as an ejecting zone 6. On the bottom of the ejecting zone 6, i.e., on the bottom side of the turntable 2, as depicted in FIGS. 1 and 3, a first evacuation opening 61 and a second evacuation opening 62 are provided.

These evacuation openings 61 and 62 are connected to, via corresponding evacuation pipes 63, a common vacuum pump 64, for example, that is an evacuation part. It is noted that, a reference numeral 65 denotes a pressure adjustment part that may be provided for each of the evacuation openings 61 and 62, or may be provided in common for the evacuation openings 61 and 62. For the purpose of the separating function of the separating zones D functioning positively, the evacuation openings 61 and 62 are provided, in a plan view, on corresponding sides in the rotation direction of the separating zones D, and the evacuation openings 61 and 62 respectively discharge the reaction gases (the BTBAS gas and the O₃ gas) exclusively. In this example, the evacuation opening 61 is provided between the gas injector 31 and the separating zone D adjacent to the gas injector 31 in the downstream side in the rotation direction. The other evacuation opening 62 is provided between the reaction gas nozzle 32 and the separating zone D adjacent to the reaction gas nozzle 32 in the downstream side in the rotation direction.

The number of evacuation openings is not limited to two, and, for example, a total of three evacuation openings may be provided such that a further evacuation opening may be provided between the separating zone D including the separating gas nozzle 42 and the second reaction gas nozzle 32 adjacent to this separating zone D in the downstream side in the rotation direction. The number of evacuation openings may be equal to or more than four. In this example, the evacuation openings 61 and 62 are provided at positions lower than the rotation table 2 so that evacuation is carried out from a space between the inner circumferential surface of the vacuum chamber 12 and the circumferential edge of the turntable 2. However, the positions of the evacuation openings 61 and 62 are not limited to the above-mentioned positions, and the evacuation openings 61 and 62 may be provided in the side wall of the vacuum chamber 1. When the evacuation openings are provided in the side wall of the vacuum chamber 1, the evacuation openings may be provided at positions higher than the turntable 2. Thus providing the evacuation openings 61 and 62, the gases on the turntable 2 flow to the outside of the turntable 2, and this configuration is advantageous from a viewpoint such that, in comparison to a case where evacuation is carried out from the top surface that faces onto the turntable 2, particles can be prevented from being caused to fly up.

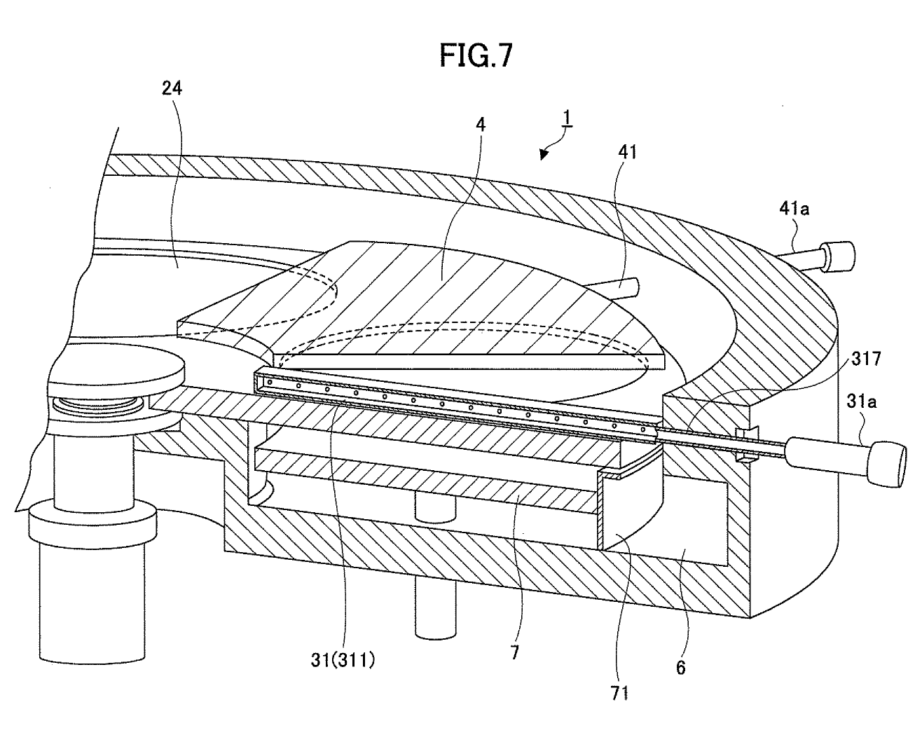

In a space between the turntable 2 and the bottom surface part 14, as depicted in FIGS. 1 and 7, heater units 7 are provided, that are heating parts and heat the wafers W via the turntable 2 to a temperature determined according to a process recipe. On the downside of the vicinity of the circumferential edge of the turntable 2, a cover member 71 is provided to surround the entire circumference of each of the heater units 7 for the purpose of dividing an atmosphere in which the heater unit 7 is located and an atmosphere from a space above the turntable 2 through the ejecting zone 6. A top edge of the cover member 71 is bent outward to have a flange shape, a space between the bent surface and the bottom surface of the turntable 2 is reduced, and thus, infiltration of the gases in the cover member 71 from the outside is avoided.

The bottom surface part 14 approaches the vicinity of a center part of the bottom surface of the turntable 2 and the core part 21, a space therebetween is narrow, further a through hole of the rotation shaft 22 passing through the bottom surface part 14 is such that a space between the rotation shaft 22 and the inner circumferential surface is narrow, and these narrow spaces communicate with the inside of the case member 20. The case member 20 is provided with a purge gas providing pipe 72 that carries out purge by providing the N₂ gas that is a purge gas to the narrow spaces. Further, to the bottom surface part 14 of the vacuum chamber 1, purge gas providing pipes 73 are provided at plural portions underneath the heater units 7, which purge spaces in which the heater units 7 are located.

By thus providing the purge gas providing parts 72 and 73, as depicted in FIG. 6 that shows a flow of the purge gas, the space from the inside of the case member 20 through the spaces in which the heater units 7 are located is purged by the N₂ gas, and the purge gas is ejected to the evacuation openings 61 and 62 from the space between the turntable 2 and the cover member 71 via the ejecting zone 6. Thereby, the BTBAS gas and the O₃ gas are prevented from flowing to one to the other of the first processing zone P1 and the second processing zone P2 via the downside of the turntable 2. Thus, the purge gas acts as a separating gas.

Further, to the center part of the top plate of the vacuum chamber 1, a separating gas providing pipe 51 is connected, which provides the N₂ gas that is the separating gas to a space 52 between the top plate 11 and the core part 21. The separating gas provided to the space 52 is discharged toward the circumferential edge of the turntable 2 along the surface on the side of the wafer placing areas via a narrow space 50 between the protrusion part 5 and the turntable 2. The space surrounded by the protrusion part 5 is filled with the separating gas, and therefore, the reaction gases (the BTBAS gas and the O₃ gas) are prevented from mixing between the first processing zone P1 and the second processing zone P2 via the center part of the turntable 2. That is, for the purpose of separating the atmospheres of the first processing zone P1 and the second processing zone 22, the film deposition apparatus is divided by the rotation center part of the turntable 2 and the vacuum chamber 1 so that a center part zone C is provided in which purging is carried out by using the separating gas and a discharge opening is provided along the rotation direction which discharges the separating gas to the surface of the turntable 2. This discharge opening corresponds to the narrow space 50 between the protrusion part 5 and the turntable 2.

Further, as depicted in FIGS. 2 and 3, in the side wall of the vacuum chamber 1, a conveyance opening 15 is provided to be used for transferring the wafer W between an external conveyance arm 10 and the turntable 2, and is opened and closed by means of a gate valve not depicted. Further, a lifting pin and a lifting mechanism (both not depicted) for transferring the wafer W are provided, which lifting pin passes through the recession part 24 as the wafer placing area and lifts the wafer W from the reverse side of the waver W, at a portion under the turntable 2 corresponding to a position for transferring the wafer W, since transfer of the wafer W is carried out from the recession part 24 on the turntable 2 at a position facing the conveyance opening 15 between the recession part 24 and the conveyance arm 10.

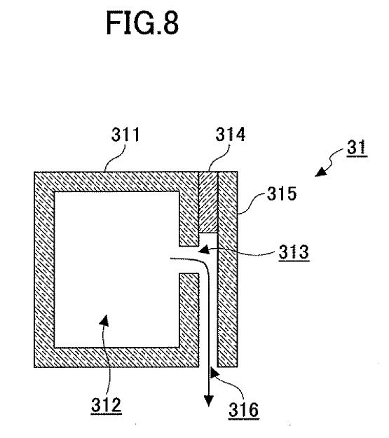

In the film deposition apparatus in the mode for carrying out the embodiments of the present invention configured as described above, the reaction gas nozzle 32 that provides the O₃ gas is such that, as mentioned above, the discharge openings 33 are disposed apart from each other provided downward. In contrast thereto, the gas injector 31 that provides the BTBAS gas, for example, has a configuration described below, for the purpose of reducing the above-mentioned undulation of a film. Now, a detailed configuration of the gas injector 31 will be described with reference to FIGS. 8-10B.

As depicted in FIGS. 8-10B, the gas injector 31 includes an injector body 311, having a long rectangular tube shape, and is made of, for example, quartz, and a guide member 315 provided to a side surface of the injector body 311. The inside of the injector body 311 is an empty space, and the empty space acts as a gas passage 312 that is used to flow the BTBAS gas therethrough provided by a gas inlet pipe 317 that is provided to a base end part of the injector body 311. As depicted in FIG. 7, the gas injector body 311 is disposed such that the base end part is directed to the side of the side wall of the chamber body 12, and the gas inlet pipe 317 is connected to the above-mentioned gas providing port 31a. A height from the surface of the turntable 2 to a bottom surface of the injector body 311 falls, for example, in a range from 1 mm through 4 mm. The gas inlet pipe 317 has an opening at a connection part of the injector body 311, and the opening acts as an inlet for introducing the reaction gas into the gas passage 312. A material of the injector body 311 is not limited to the above-mentioned quartz, and the injector body 311 may be made of ceramic.

As depicted in FIGS. 8, 9 and 10A, plural, for example, 67 gas outflow openings 313 each having a bore diameter of, for example, 0.5 mm, are disposed at intervals of, for example, 5 mm, along a longitudinal direction of the injector body 311, on a side wall part on one side of the injector body 311, for example, a side wall on the upstream side in the rotation direction of the turntable 2. The gas outflow openings 313 provide the BTBAS gas from the gas passage 312 uniformly in a direction in which a gas discharge opening 316 extends.

The injector body 311 in the mode for carrying out the embodiments of the present invention has a shape of a rectangular tube as mentioned above. The side wall part having the gas outflow openings 313 is a flat part, and it is preferable that the side wall part be disposed perpendicular to the turntable 2. The side wall part being thus disposed perpendicular to the turntable 2 means that, it is not necessary to be limited to a case of the side wall part being strictly perpendicular, and includes a case where the side wall part is disposed to have a tilt on the order of ±5° from a plane perpendicular to the turntable 2.

Further, on the side wall part of the injector body 311 on which the gas outflow openings 313 are disposed, the guide member 315 is fixed to face toward the gas outflow openings 313. The guide member 315 is fixed to the side wall part via a space adjusting member 314, for example, and thus, the guide member 315 is fixed to the side wall part in such a manner that the guide member 315 and the side wall are in parallel to one another. The guide member 315 is made of, for example, quartz, guides the BTBAS gas discharged from the gas outflow openings 313 to a flowing direction of the BTBAS gas toward the turntable 2, and also, disperses the flow of the gas so as to avoid a reflection of the gas outflow openings in a film to be formed in a film deposition process. The above-mentioned guide member 315 being in parallel to the side wall part in which the outflow openings 313 are provided is not limited to a case where both members are disposed strictly in parallel to one another, and includes a case where, for example, the guide member 315 is disposed to have a tilt on the order of ±5° from the side wall part. The guide member 315 may also be made of ceramic.

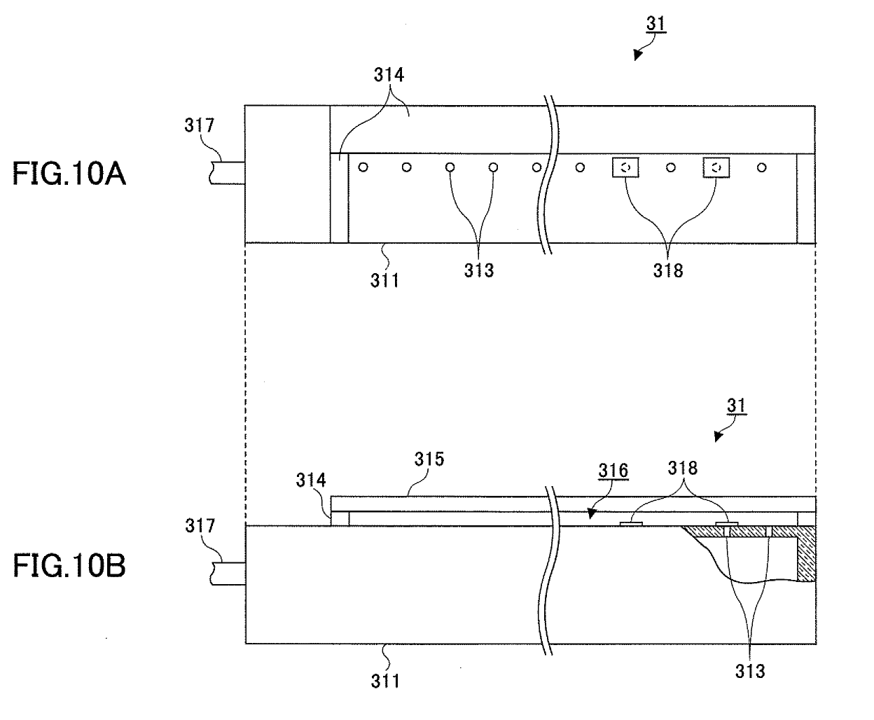

FIG. 10A is a side view of the gas injector 31 where the guide member 315 is removed. The space adjusting member 314 includes, for example, plural sheet members made of quartz and having equal thicknesses, and are disposed at a top side and left and right sides of an area in which the gas outflow openings 313 are disposed so as to surround the area on the side wall part of the injector body 311. In this example, the thickness of the space adjusting member 314 is, for example, 0.3 mm, and the guide member 315 is fixed to the injector body 311 via the space adjusting member 314, for example, as being bolted down or so. The space adjusting member 314 may also be made of ceramic.

By providing the above-described configuration of the gas injector 31, the slit-shaped gas discharge opening 316 is provided along one edge of the side wall part that is a flat part, between an outer surface of the side wall part and the guide member 315, for example, as depicted in FIG. 10B that is a bottom plan view, and the gas discharge opening 316 discharges the BTBAS gas discharged from the gas outflow openings 313 to the wafer W. The gas injector 31 is disposed in the vacuum chamber 1 where the gas discharge opening 316 faces toward the turntable 2. Further, as mentioned above, the thickness of the space adjusting member 314 is 0.3 mm, and a width of the gas discharge opening 316 is also 0.3 mm.

Further, in a case where the bolting down is used as mentioned above, the space adjusting member 314 and/or the guide member 315 is detachable from the injector body 311. Therefore, it is possible to use the space adjusting member 314 having a different thickness to adjust the width of the slit of the gas discharge opening 316, according to operating conditions such as sorts and/or supply amounts of the reaction gases, the rotational speed of the turntable 2, and so forth, when the operating conditions are changed, for example. Further, in a case where the guide member 315 is detachable, some of the gas outflow openings 313 may be easily covered by a seal 318 made of a material that is thermally and chemically highly stable, for example, Kapton (registered trademark), and may then be easily removed, as depicted in right side parts of FIGS. 10A and 10B. Thereby, it is possible to change disposing intervals of the gas outflow openings 313, make disposing intervals of the gas outflow openings 313 to differ between the base end side and the extending end side of the gas injector 31, or so, according to a change in the reaction gases, operating conditions, and so forth.

Returning to the description of the entire film deposition apparatus, as depicted in FIGS. 1 and 3, a control part 100 having a computer is provided to control operation of the entire film deposition apparatus in the film deposition apparatus according to the mode for carrying out the embodiments of the present invention. A computer program for operating the film deposition apparatus is stored in a memory of the control part 100. In the computer program, a group of steps is incorporated such as to carry out operations of the film deposition apparatus described later. The computer program is installed in the control part 100 from a recording medium such as a hard disk, a compact disc, a magneto-optical disc, a memory card, a flexible disk, or such.

Next, operations of the film deposition apparatus in the mode for carrying out the embodiments of the present invention will be described. First, the gate valve not depicted is opened, and the wafer W is transferred to the recession part 24 on the turntable 2 by means of the conveyance arm 10 via the conveyance opening 15 from the outside. The transfer is carried out as a result of, when the recession part 24 stops at a position at which the recession part 24 faces the conveyance opening 15, the lifting pins not depicted moving upward and downward from the bottom side of the vacuum chamber 1 via the through holes of the bottom surface of the recession part 24. Then, while the turntable is intermittently rotated, such transfer of the wafers W is carried out, and thus, the wafers W are placed on the five recession parts 24 of the turntable 2, respectively. Then, the vacuum pump 64 is operated, a pressure adjusting valve of the pressure adjusting part 65 is fully opened, the space, including the respective processing zones P1 and P2, is evacuated to have a previously set pressure, and the wafers W are heated by the heater units 7 while the turntable 2 is rotated clockwise. In more detail, the turntable 2 is previously heated by the heater units 7 to, for example, 300° C., and the wafers W are heated as a result of being placed on the turntable 2.

Parallel to the operation of heating the wafers W, the N₂ gas of an amount equal to those of the reaction gases, separating gas and purge gas that will be provided after a film deposition operation is started, is provided to the vacuum chamber 1, and a pressure adjustment in the vacuum chamber 1 is carried out. For example, the N₂ gas in respective amounts, such as, 100 sccm from the gas injector 31, 10,000 sccm from the reaction gas nozzle 32, 20,000 sccm from each of the separating gas nozzles 41 and 42, and 5,000 sccm from the separating gas providing pipe 51, is provided to the vacuum chamber 1, and opening and closing operations of the pressure adjusting valve is carried out in the pressure adjusting part 65 so that a pressure in each of the processing zones P1 and P2 becomes a predetermined pressure set value, for example, 1,067 Pa (8 Torr). It is noted that a predetermined amount of the N₂ gas is provided from each of the purge gas providing parts 72 and 73.

Next, when it is confirmed that a temperature of the wafers W becomes a set temperature by means of a temperature sensor (not depicted), and it is determined that the pressure in each of the first and second processing zones P1 and P2 becomes the set pressure, gases to be provided by the gas injector 31 and reaction gas nozzle 32 are switched to the BTBAS gas and the O₃ gas, respectively, and a film deposition operation to the wafers W is started. At this time, it is preferable that the switching of the gases in each of the gas injector 31 and the reaction gas nozzle 32 be carried out slowly, so that the total amount of the gases provided to the vacuum chamber 1 is not changed suddenly.

Then, since the wafers W pass through the first and second processing zones P1 and 22 alternately because of rotation of the turntable 2, the BTBAS gas is adsorbed on each wafer W, then the O₃ gas is adsorbed on the wafer W, BTBAS molecules are oxidized, one or plural layers of silicon oxide are formed, thus molecular layers of silicon oxide are layered in sequence, and thus, a silicon oxide film with a predetermined thickness is formed.

Behavior of the BTBAS gas provided by the gas injector 31 at this time will now be described in detail. The BTBAS gas provided by the gas providing pipe 317 flows in the gas passage 312 from the base end through the extending end of the injector body 311, and also flows out from the respective gas outflow openings 313 provided in the side wall part of the injector body 311. At this time, the guide member 315 is provided at a position facing toward the respective gas outflow openings 313. Therefore, as depicted in FIG. 8, for example, the guide member 315 guides the BTBAS gas so that the BTBAS gas discharged from the respective gas outflow openings 313 flows downward, and thus, the BTBAS gas flows toward the gas discharge opening 316.

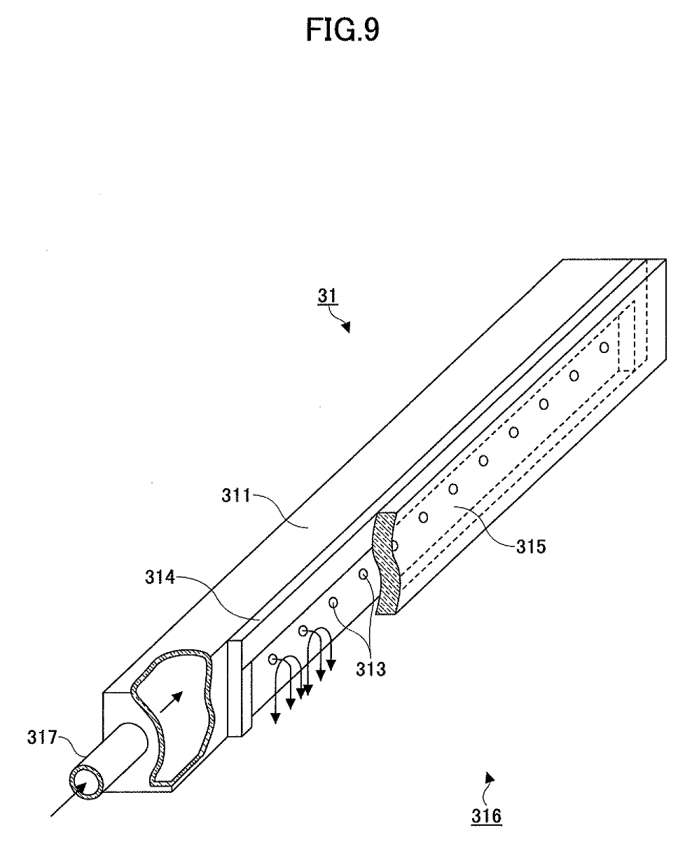

At this time, since the BTBAS gas discharged from the gas outflow openings 313 hits the guide member 315 and a flowing direction is thus changed, the gas diffuses in left and right directions in which the slit-shaped gas discharge opening 31 extends when the gas hits the guide member 315, and after that, the gas flows downward, as diagrammatically depicted in FIG. 9. Since the gas outflow openings 313 are disposed adjacent to each other in the longitudinal direction of the injector body 311 as descried above, the gas discharged from each of the gas outflow openings 313 flows in such a manner that the gas is mixed together in the longitudinal direction of the gas injector 31 when hitting the guide member 315 and diffusing in the left and right directions. Thus, the gas flows in such a manner that the gas reaches the slit-shaped gas discharge opening 316 while a gas concentration is made uniform in the longitudinal direction of the gas injector 31, and is provided to the processing zone P1 as forming a long and narrow strip-shaped flow.

Since the BTBAS gas is thus provided to the processing zone P1 while being mixed in the longitudinal direction of the gas injector 31, it is possible that the gas can reach the surfaces of the wafers W passing through the processing zone P1 at a reduced concentration difference in comparison to the above-mentioned case where the nozzle of the reference example is used to provide the gas. As a result, even in a case where the rotational speed of the turntable 2 is high and the wafer W passes through the processing zone P1 before adsorption of the reaction gas onto the wafer W reaches equilibrium, the BTBAS gas is adsorbed on the surface of the wafer W at a reduced concentration difference between the positions of the gas outflow openings 313 and the positions therebetween, and thus, it is possible to form a film having an undulation that is smaller than that in comparison to the nozzle in the reference example.

Further, since the BTBAS gas is provided to the slit-shaped discharge opening 316 via the small gas outflow openings 313 each having a bore diameter of 0.5 mm, for example, the flow rate when the gas flows toward the gas discharge opening 316 from the gas passage 312 in the injector body 311 is small. Therefore, it is possible to avoid occurrence of a phenomenon that occurs in a case where a slit is provided on a bottom side of the gas nozzle in the reference example for the purpose of reducing the above-mentioned phenomenon of undulation as in the reference example, that is, a phenomenon that conduction is large when BTBAS gas flows through the slit, a large concentration difference occurs between the extending end and the base end of the nozzle, and a film thus formed is thick on the base end side and thin on the extending end side on the surface of the wafer W, for example.

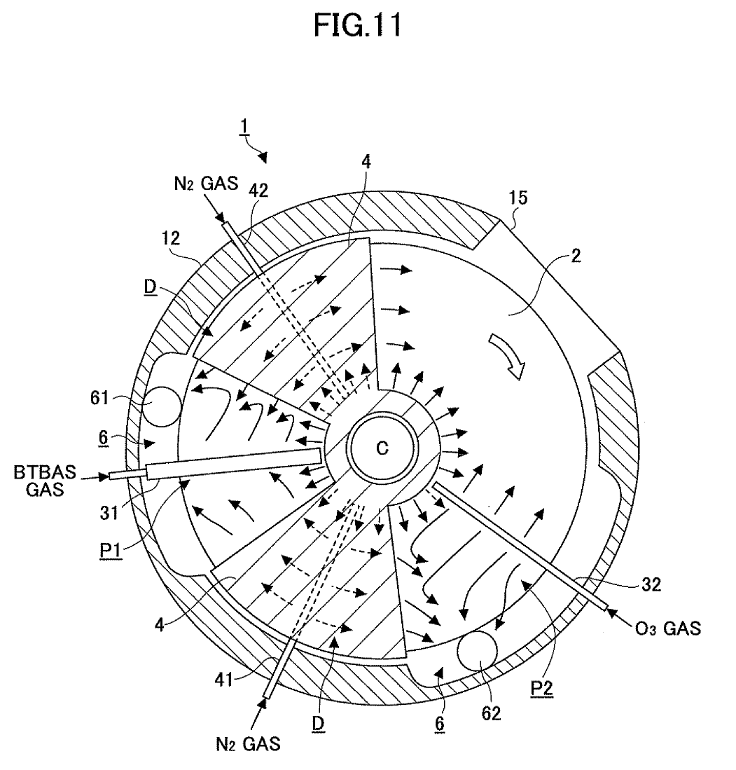

Next, gas flow in the entirety of the vacuum chamber 1 will be described. The N₂ gas that is the separating gas is provided from the separating gas providing pipe 51 connected to the center part of the top plate 11, and thereby the N₂ gas is discharged along the surface of the turntable 2 from the center part zone C, i.e., from between the turntable 2 and the center part. In this example, in the inner circumferential wall of the chamber body 12 along the space below the second ceiling surface 45 on which the gas injector 31 and the reaction gas nozzle 32 are disposed, the inner circumferential wall is cut out as mentioned above, thus a wide space is provided, and the evacuation openings 61 and 62 are provided on the bottom of the wide space. Therefore, a pressure in the space under the second ceiling 45 becomes higher than a pressure in each of the narrow spaces under the first ceiling surfaces 44 and the above-mentioned center part zone C. FIG. 11 diagrammatically depicts a manner of gas flow when the gases are discharged from the respective portions. The O₃ gas is discharged downward from the reaction gas nozzle 32, hitting the surface of the turntable 2 (both of the surfaces of the wafers W and the surface of the other areas of the turntable 2), and flowing toward the upstream side in the rotation direction along the surface flows into the ejecting zone 6 between the circumferential edge of the turntable 2 and the inner circumferential wall of the vacuum chamber 1 with being pressed back by the N₂ gas flowing from the upstream side, and is ejected through the evacuation opening 62.

Further, the O₃ gas discharged downward from the reaction gas nozzle 32, hitting the surface of the turntable 2 and flowing toward the downstream side in the rotation direction affected by a flow of the N₂ gas discharged from the center part zone C and a suction function of the evacuation opening 62 for being directed to the evacuation opening 62, but a part thereof goes toward the separating zone D adjacent on the downstream side for flowing to under the sectorial projection part 4. However, the height and the length in the circumferential direction of the ceiling surface 44 of the projection part 4 are set to be able to avoid infiltration of the gas to under the ceiling surface 44 in process parameters including flow rates of the respective gases. Therefore, also as depicted in FIG. 4B, the O₃ gas can hardly flow to under the sectorial projection part 4 or, even when a little can flow to under the sectorial projection part 4, the O₃ gas cannot reach the vicinity of the separating gas nozzle 41. Then, the O₃ gas is pressed back to the upstream side in the rotation direction, i.e., to the side of the processing zone P2 by the N₂ gas discharged by the separating gas nozzle 41, and is ejected through the evacuation opening 62 via the ejecting zone 6 from the space between the circumferential edge of the turntable 2 and the inner circumferential wall of the vacuum chamber 1, together with the N₂ gas discharged by the center part zone C.

The BTBAS gas provided flowing downward from the gas injector 31 and going toward the upstream side and downstream side in the rotation direction along the surface of the turntable 2 cannot at all irrupt to under the sectorial projection parts 4 adjacent on the upstream side and the downstream side in the rotation direction, or, even when it can irrupt there, is then pressed back to the side of the processing zone P1, and ejected through the evacuation opening 61 via the ejecting zone 6 from the space between the circumferential edge of the turntable 2 and the inner circumferential wall of the vacuum chamber 1 together with the N₂ gas discharged from the center part zone C. That is, in each separating zone D, although infiltration of the BTBAS gas or the O₃ gas that is the reaction gas flowing in the atmosphere is avoided, gas molecules having been adsorbed on the surfaces of the wafers pass through the separating zones, i.e., under the low ceiling surfaces 44 provided by the sectorial projection parts 4 as they are, and contribute to film deposition.

Thus, the BTBAS gas provided by the gas injector 31 is ejected to the evacuation opening 61 as being carried by flow of the N₂ gas flowing around. In this situation, in a case where the BTBAS gas is provided while a flowing direction of the BTBAS gas has a large angle with respect to the turntable 2, for example, the BTBAS gas is easily caused to fly upward by the N₂ gas flowing around, and may be ejected without reaching the surfaces of the wafers W, which may thus result in degradation in a film deposition rate.

In this point, the gas injector 31 in the mode for carrying out the embodiments of the present invention is configured such that, the side wall part of the injector body 311 in which the outflow openings are provided is disposed as being perpendicular to the turntable 2, and further, the guide member 315 is disposed parallel to the side wall part. Therefore, the strip-shaped flow of the BTBAS gas provided to the processing zone P1 via the discharge opening 316 provided therebetween is perpendicular to the turntable 2. As a result, a distance from the gas discharge opening 316 of the gas injector 31 to the turntable 2 becomes the shortest, and also, an inertial force applied to the BTBAS gas exiting the opening is such that force in a perpendicular direction toward the turntable 2 is the maximum. Accordingly, in comparison to a case where the gas is provided in a direction inclined with respect to the turntable 2, the BTBAS gas is provided to the processing zone P1 so that the BTBAS gas is not easily caused to fly upward by the surrounding flow of the N₂ gas.

Returning to the description of gas flow in the entirety of the vacuum chamber 1, when the BTBAS gas in the first processing zone P1 (the O₃ gas in the second processing zone P2) irrupts into the center part zone C, the infiltration is avoided by the separating gas, or, even when the gas irrupts, the gas is pressed back, since the separating gas is discharged toward the periphery of the turntable from the center part zone C as depicted in FIGS. 6 and 11. Therefore, the BTBAS gas (O₃ gas) is prevented from irrupting into the second processing zone P2 (first processing zone P1) through the center part zone C.

Then, in the separating zone D, the peripheral part of the sectorial projection part 4 is bent downward, the space between the bent part 46 and the outer end surface of the turntable 2 becomes narrow as mentioned above, and thus, passage of the gas is substantially avoided. Therefore, the BTBAS gas in the first processing zone P1 (the O₃ gas in the second processing zone P2) is also prevented from flowing into the second processing zone P2 (first processing zone P1) via the outside of the turntable 2. Accordingly, the two separating zones D completely separate the atmosphere in the first processing zone P1 and the atmosphere in the second processing zone P2, and the BTBAS gas is ejected to the evacuation opening 61 and the O₃ gas is ejected to the evacuation opening 62. As a result, both the reaction gases, in this example, the BTBAS gas and the O₃ gas, do not mix together on the wafers W even in the atmosphere. It is noted that, in this example, since the N₂ gas is used to purge the space below the turntable 2, it is not possible at all that the gas flowing into the ejecting zone 6 passes through under the turntable 2 and thus, for example, it is not possible that the BTBAS gas flows into the zone in which the O₃ gas is provided. When the film deposition operation is thus finished, each wafer W is conveyed out in an operation by means of the conveyance arm 10 reverse to the operation of conveying the wafer W in.

Processing parameters in one example will now be described. The rotational speed of the turntable 2 falls within a range from 1 rpm through 500 rpm, for example, in a case where a wafer W having a diameter of 300 mm is the to-be-processed substrate. In this case, a process pressure is, for example, 1,067 Pa (8 Torr); a heating temperature of the wafer W is, for example, 350° C.; flow rates of the BTBAS gas and the O₃ gas are, for example, 100 sccm and 10,000 sccm, respectively; and a flow rate of the N₂ gas from the separating gas nozzles 41 and 42 is, for example, 20,000 sccm. A flow rate of the N₂ gas from the separating gas providing pipe 51 at the center part of the vacuum chamber 1 is, for example, 5,000 sccm. Further, the number of cycles of providing the reaction gases to a single wafer W, i.e., the number of times of the wafer W passing through each of the processing zones P1 and P2 depends on a target film thickness, is large, for example, 6,000 times.

Advantages of the above-described mode for carrying out the embodiments of the present invention are as follows: the BTBAS gas discharged from the plural gas outflow openings 313 provided in the side wall part of the injector body 311 included in the gas injector 31 is guided by the guide member 315, and is provided via the slit-shaped gas discharge opening 316 extending along the longitudinal direction of the injector body 311. Therefore, when the reaction gas is guided by the guide member 315, the reaction gas can be diffused in the directions in which the slit extends. As a result, in the film deposition apparatus in the mode for carrying out the embodiments of the present invention in which the reaction gas from the gas injector 31 is provided to the wafers W placed on the placing areas of the turntable 2 and the reaction gas is adsorbed on the surfaces of the wafers W, it is possible to provide the gas having a uniform concentration in the direction in which the injector body 311 extends. Thereby, in comparison to a case where the gas discharged from gas outflow openings provided in a wall of an injector body is directly made to blow is used, such a problematic situation that gas amounts adsorbed on the substrate are different between a zone for which the gas outflow opening is provided and the other zones can be avoided, and thus, it is possible to form a uniform film.

Further, when the BTBAS gas is made to hit the guide member 315 and thus is guided, the gas is flowed out via the gas outflow openings 313 that are disposed in the direction in which the injector body extends. The gas outflow openings 313 have small flow rates in comparison to, for example, a slit or such. Therefore, it is possible to avoid a problematic situation where, for example, a concentration difference occurs between the base end of the gas injector 31 close to the gas source of the BTBAS gas and the extending end far away from the gas source, and a thickness of a formed film becomes thick on the base end side on the surface of the wafer W and thin on the extending end side along the direction in which the gas injector 31 extends.

Further, the gas injector 31 is disposed in such a manner that the side wall part of the injector body 311 is disposed perpendicular to the turntable 2, and also, the guide member 315 is disposed parallel to the side wall part. Thereby, the BTBAS gas is provided in such a manner that a flow direction of the BTBAS gas is perpendicular to the turntable 2. As a result, in comparison to a case where the gas is provided in an inclined direction with respect to the turntable 2, it is possible to provide the BTBAS gas to the processing zone 21 so that the BTBAS gas is not easily caused to fly upward by a surrounding flow of the N₂ gas, and it is possible to efficiently adsorb the BTBAS gas on the surfaces of the wafers W.

Further, in the gas injector 31 according to the mode for carrying out the embodiments of the present invention, the guide member 315 and the space adjusting member 314 may be detachable from the injector body 311. Therefore, it is possible to change disposing intervals of the gas outflow openings 313 by, for example, sticking seals 318 over some of the gas outflow openings 313; it is possible to change a width of the slit of the gas discharge opening 316 by changing a thickness of the space adjusting member 314; or so, after removing the guide member 315, and thus, it is possible to easily modify the gas injector 31, and it is possible to improve flexibility in BTBAS gas providing conditions.

Further, in the film deposition apparatus in the mode for carrying out the embodiments of the present invention, the plural wafers W are disposed in the rotation direction of the turntable 2, the turntable 2 is rotated, the first processing zone P1 and the second processing zone P2 are alternately passed through thereby, and thus, so-called ALD (or MLD) is carried out. Thereby, in comparison to the above-mentioned case where the single-wafer film deposition apparatus is used, a time for purging the reaction gases becomes unnecessary, and thus, it is possible to carry out film deposition with high throughput.

Next, a gas injector 31a according to another mode for carrying out the embodiments of the present invention will now be described. A film deposition apparatus applying the gas injector 31a according to this other mode for carrying out the embodiments of the present invention is the same as that described above with reference to FIGS. 1-7, and duplicate descriptions therefor will be omitted. Further, for components having the same function as those of the gas injector 31 described above with reference to FIGS. 8-10B, the same reference numerals are given.

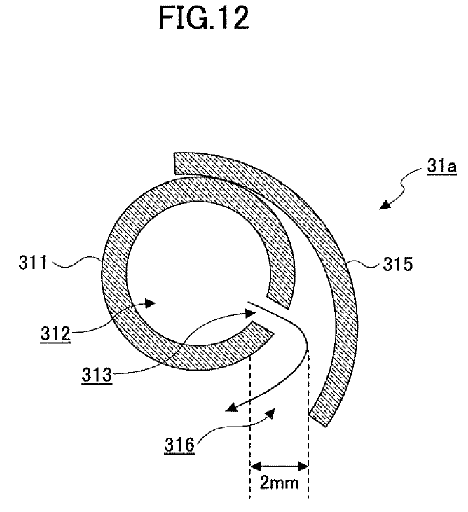

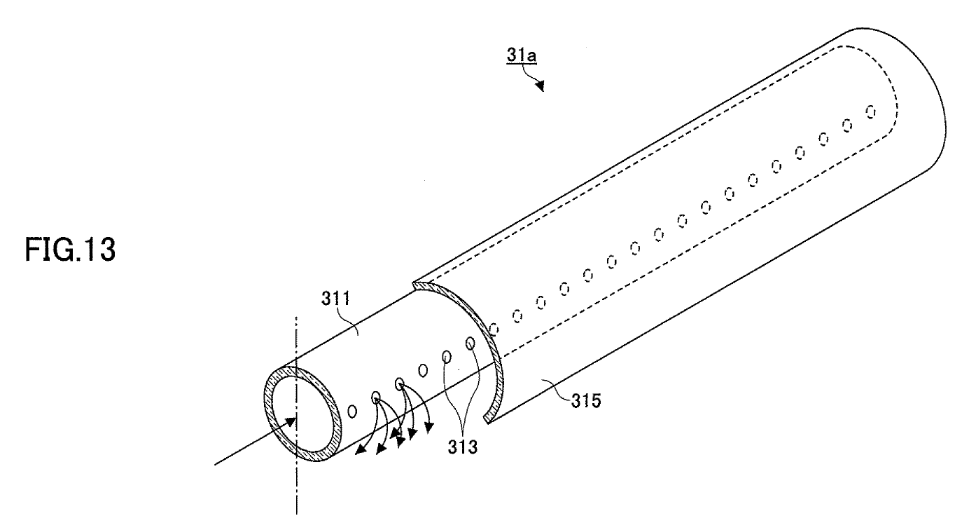

The gas injector 31a in the other mode for carrying out the embodiments of the present invention is different from the gas injector 31 in the above-mentioned mode for carrying out the embodiments of the present invention in which the rectangular tube injector body 311 and the flat guide member 315 are provided, in that, as depicted in FIGS. 12 and 13, an injector body 311 is configured as a cylindrical member, and the guide member 315 is configured as a member having a circular-arc section.

In this example, on a side wall surface of the cylindrical injector body 311 made of quartz, for example, plural, for example, 34 gas outflow openings 313 having a diameter of 0.5 mm, for example, are disposed along a longitudinal direction of the injector body 311 at intervals of 10 mm for example. Further, the guide member 315 is configured such that, for example, one side extending along a longitudinal direction of a member having a circular-arc longitudinal section obtained from a cylinder having a diameter larger than that of the injector body 311 being cut out in a radial direction is fixed to an outer surface of the injector body 311 by means of welding, for example. In other words, a section of the guide member 315 is a circular arc extending along with the outer surface of the injector body 311.

A slit-shaped gas discharge opening 316 for discharging the BTBAS gas is provided between an outer surface side wall part which is a wall part of the injector body 311 in which the gas outflow openings 313 are provided, and the guide member 315. As depicted in FIG. 13, the BTBAS gas discharged from the gas outflow openings 313 flows while hitting the guide member 315 and spreading to left and right sides, is mixed in the longitudinal direction of the gas injector 31a, and is provided to the processing zone P1. As a result, also in the gas injector 31a in the other mode for carrying out the embodiments of the present invention, it is possible to provide the BTBAS gas to the processing zone P1 with a reduced concentration difference, and it is possible to form a film with reduced undulation in comparison to the nozzle in the reference example.

Further, also in this example, the gas injector 31a provides the BTBAS gas from the gas passage 312 via the gas outflow openings 313 having small flow rates. Therefore, in comparison to a case where a slit having a large flow rate is provided in a bottom surface of a gas nozzle as in the reference example for the purpose of reducing the undulation phenomenon, for example, a concentration difference between the base end and the extending end of the gas injector 31a is small and it is possible to form a film having a uniform thickness between the base end side and the extending end side on a surface of a wafer W.

In the gas injector 31a in the other mode for carrying out the embodiments of the present invention, a width of the slit-shaped gas discharge opening 316 viewed from the bottom is, for example, 2 mm, as depicted in FIG. 12. It is possible to adjust this opening width by changing an angle at which the guide member 315 is fixed to the injector body 311, and by changing a difference in a diameter between the injector body 311 and the guide member 315. As depicted in FIG. 12, the BTBAS gas is provided to the processing zone P1 with an oblique inclination from a direction in which the gas discharge opening 316 is opened. Therefore, a distance from the gas discharge opening 316 to the turntable 2 is long, and further, an inertia force in a lateral direction is applied to a flow of the BTBAS gas. Therefore, in comparison to the gas injector 31 described above with reference to FIG. 9 and so forth, the BTBAS gas may be easily caused to fly upward by the surrounding N₂ gas. In this point, the gas injector 31 has higher efficiency when providing the BTBAS gas to the wafers W. Further, the above-mentioned gas injector 31 in which the opening width of the opening part is adjusted by using the space adjusting member 314 is advantageous such that adjustment of the opening width is easy.

The gas injectors 31 and 31a according to the above-mentioned modes for carrying out the embodiments of the present invention are applied as the first reaction gas providing part that provides the BTBAS gas as a reaction gas. However, a gas applicable to the gas injectors 31 and 31a is not limited to the BTBAS gas. For example, the gas injectors 31 and 31a may be applied as the second reaction gas providing part, and may provide the O₃ gas that is the second reaction gas.

Further, in the above-mentioned respective modes for carrying out the embodiments of the present invention, the gas discharge opening 316 is disposed in the upstream side in the rotation direction of the turntable 2 as an example depicted in FIGS. 4A and 4B, for example. However, the position of disposing the gas discharge opening 316 is not limited to that described above for the above-mentioned modes for carrying out the embodiments of the present invention. For example, the gas injector 31 may be configured such that the side wall part in which the gas outflow openings 313 are disposed, the space adjusting member 314 and the guide member 315 are disposed in bilateral symmetry to the example depicted in FIG. 8, and the gas injector 31 may be disposed on the downstream side in the rotation direction of the turntable 2.

The reaction gases that may be used in the film deposition apparatus according to the above-mentioned modes for carrying out the embodiments of the present invention are, in addition to the above-mentioned examples, dichlorosilane (DCS), hexachlorodisilane (HCD), Trimethyl Aluminum (TMA), tetrakis-ethyl-methyl-amino-zirconium (TEMAZr), tris(dimethyl amino) silane (3DMAS), tetrakis-ethyl-methyl-amino-hafnium (TEMHf), bis(tetra methyl heptandionate) strontium (Sr(THD)₂), (methyl-pentadionate)(bis-tetra-methyl-heptandionate) titanium (Ti(MPD)(THD)), monoamino-silane, or the like.

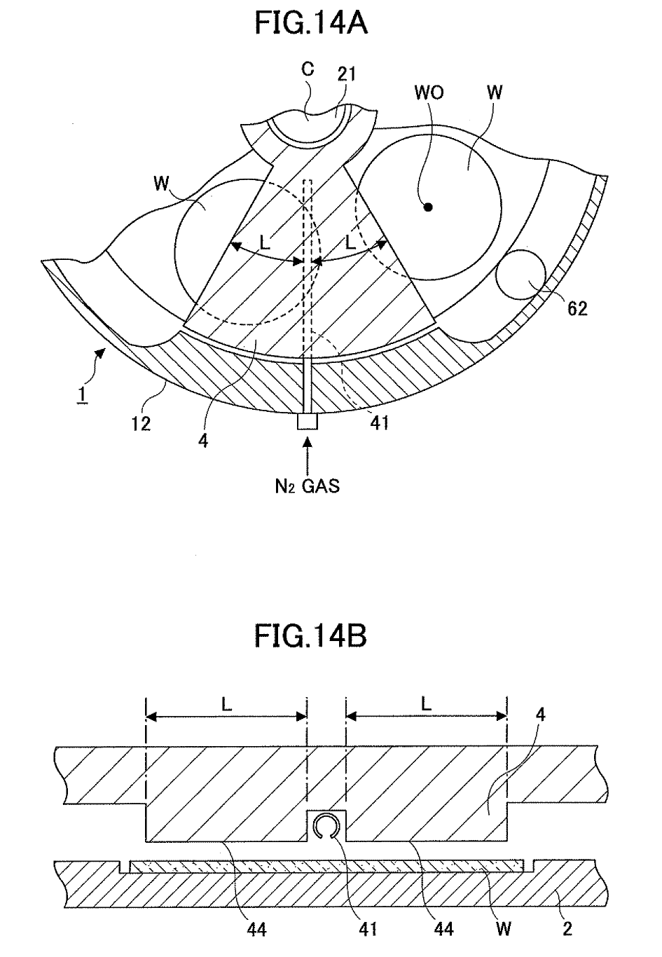

The first ceiling surface 44 that provides the narrow space in the position of the separating gas nozzle 41 (42) may preferably have a width dimension L of 50 mm or more along the rotation direction of the turntable 2 at a portion at which the center WO of the wafer W passes, in a case where, for example, the wafer W of 300 mm diameter is used as a to-be-processed substrate, as the separating gas providing nozzle 41 is typically depicted in FIGS. 14A and 14B. In order to effectively avoid infiltration of the reaction gas to the space (narrow space) below the projection part 4 from both sides of the projection part 4, in a case where the above-mentioned width dimension L is short, it is necessary to reduce a distance between the first ceiling surface 44 and the turntable 2 accordingly. Further, when the distance between the first ceiling surface 44 and the turntable 2 is set to be a certain dimension, the speed of the turntable 2 becomes higher as a position becomes farther away from the rotation center, the width dimension L required for obtaining the reaction gas infiltration avoiding function becomes larger as the position is farther away from the rotation center of the turntable 2. In consideration of this viewpoint, when the above-mentioned width dimension L is smaller than 50 mm at the portion at which the center WO of the wafer W passes through, it is necessary to considerably reduce the distance between the circuit ceiling surface 44 and the turntable 2. Therefore, in order to avoid collision between the turntable 2 or the wafer W and the ceiling surface 44 while the turntable 2 is rotated, it is necessary to take measures to reduce the deflection of the turntable 2 as much as possible. Further, the higher the rotational speed of the turntable 2 becomes, the more easily the reaction gas irrupts into the space under the projection part 4 from the upstream side of the projection part 4. Therefore, when the width dimension L is smaller than 50 mm, the rotational speed of the turntable 2 should be reduced, which is not advantageous from a throughput viewpoint. Therefore, it is preferable that the width dimension L be equal to or more than 50 mm. However, when the width dimension L is less than 50 mm, the advantageous effect of the modes for carrying out the embodiments of the present invention can still be obtained. That is, it is preferable that the width dimension L fall within a range from 1/10 through 1/1 of the diameter of the wafer W, and it is more preferable that the width dimension L be equal to or more than approximately ⅙ of the diameter of the wafer W. It is noted that, in FIG. 14A, for the purpose of convenience in illustration, the recession parts 24 are omitted.

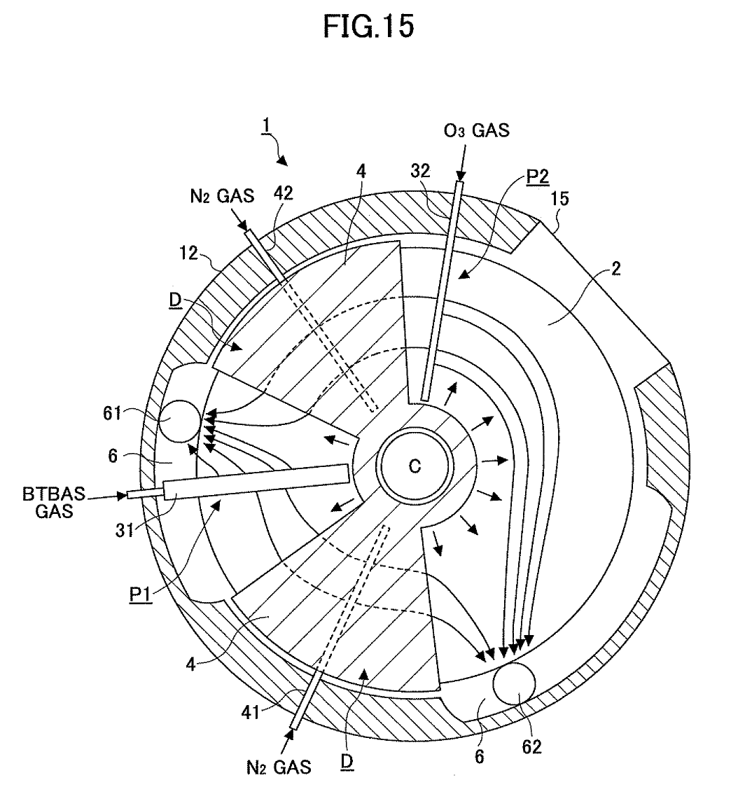

Another example of respective layouts of the processing zones P1 and P2 and the separating zones D than those of the above-mentioned mode for carrying out the embodiments of the present invention will now be described. FIG. 15 depicts an example in which the reaction gas nozzle 32 providing the O₃ gas is located on the upstream side in the rotation direction of the turntable 2 with respect to the conveyance opening 15, and, also in the layouts, the same advantages can be obtained.

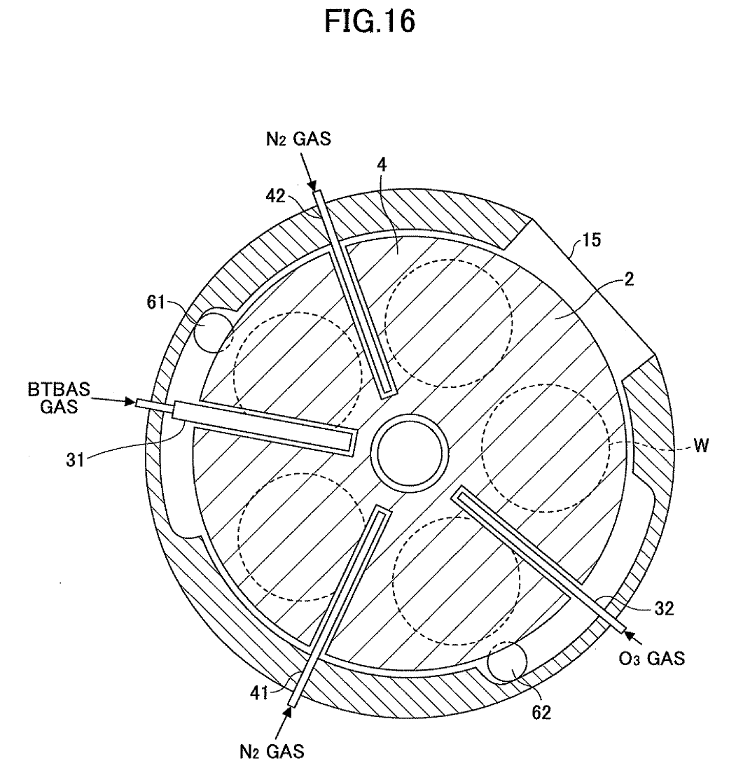

Further, the gas injectors 31 and 31a (FIG. 16 depicts only the gas injector 31) according to the modes for carrying out the embodiment of the present invention may be applied to a film deposition apparatus configured as mentioned below. That is, although it is necessary to provide the low ceiling surface (first ceiling surface) 44 for providing the narrow spaces on both sides of the separating gas nozzle 41 (42), further, similar low ceiling surfaces may be provided also on both sides of the gas injector 31 or 31a (the reaction gas nozzle 32) as depicted in FIG. 16, and these ceiling surfaces may be made continuous. In other words, the projection part 4 may be provided throughout the entire area facing toward the turntable 2, except portions for the separating gas nozzles 41 and 42, the gas injector 31 or 31a and the reaction gas nozzle 32. In this configuration, from another viewpoint, the first ceiling surfaces 44 on both sides of the separating gas nozzle 41 (42) extend through the gas injector 31 or 31a and the reaction gas nozzle 32. In this case, the separating gas diffuses to both sides of the separating gas nozzle 41 (42), the reaction gas diffuses to both sides of the gas injector 31 or 31a (the reaction gas nozzle 32), and both gases merge under the projection part 4 (narrow space). However, these gases are ejected via the evacuation openings 61 (62) located between the gas injector 31 or 31a (reaction gas nozzle 32) and the separating gas nozzle 42 (41).

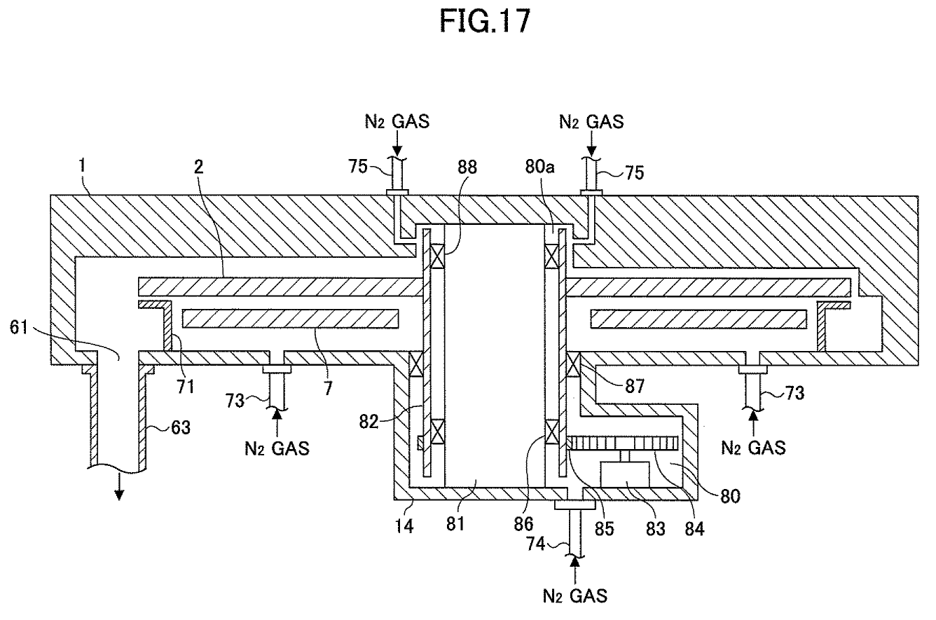

In the above-mentioned modes for carrying out the embodiments of the present invention, the rotation shaft 22 of the turntable 2 is located at the center part of the vacuum chamber 1, and the separating gas is used to purge the space between the center part of the turntable 2 and the top surface part of the vacuum chamber 1. However, a film deposition apparatus to which the gas injectors 31 and 31a are applicable may be configured as depicted in FIG. 17 for example. In the film deposition apparatus depicted in FIG. 17, a bottom surface part 14 in a center zone of the vacuum chamber 1 projects downward to provide a holding space 80 for a driving part. Further, a recession part 80a is provided on a top surface of the center zone of the vacuum chamber 1, a support 81 is inserted between the bottom of the holding space 80 and the top surface of the recession part 80a at the center part of the vacuum chamber 1, and the BTBAS gas from the gas injector 31 and the O₃ gas from the reaction gas nozzle 32 are prevented from mixing together via the center part of the vacuum chamber 1.

A mechanism for rotating a turntable 2 is such that a rotation sleeve 82 is provided to surround the support 81, and the ring-shaped turntable 2 is provided along the rotation sleeve 82. Then, a driving gear 84 is provided which is driven by a motor 83 in the holding space 80, and the rotation sleeve 82 is rotated by the driving gear 84 via a gear part 85 provided on the lower, outer circumference of the rotation sleeve 82. Reference numerals 86, 87 and 88 denote bearing parts. A purge gas providing pipe 74 is connected to the bottom of the holding space 80, and a purge gas pipe 75 for providing a purge gas to a space between a side surface of the recession part 80a and a top end part of the rotation sleeve 82 is connected to a top part of the vacuum chamber 1. In FIG. 17, left and right openings that provide a purge gas to the space between the side surface of the recession part 80a and the top end part of the rotation sleeve 82 are depicted. However, it is preferable to design the number of opening parts (purge gas providing openings) to be provided for the purpose of preventing the BTBAS gas and the O₃ gas from mixing together via a zone in proximity to the rotation sleeve 82.

In the mode for carrying out the embodiments of the present invention depicted in FIG. 17, when viewed from the side of the turntable 2, the space between the side surface of the recession part 80a and the top end part of the rotation sleeve 82 acts as the separating gas discharge opening, and the center part zone located at the center part of the vacuum chamber 1 is provided by the separating gas providing opening, the rotation sleeve 82 and the support 81.

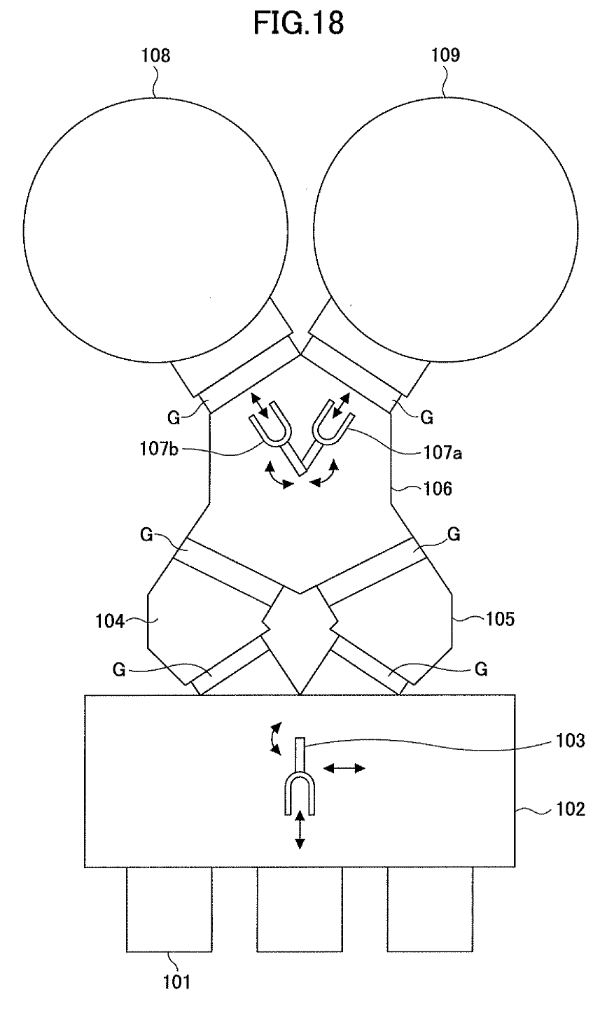

FIG. 18 depicts a substrate processing apparatus using the film deposition apparatus described above. In FIG. 18, reference numeral 101 denotes a sealed conveyance container called hoop that holds 25 wafers W, for example; reference numeral 102 denotes an atmospheric conveyance chamber in which a conveyance arm 103 is disposed; reference numerals 104 and 105 denote load lock chambers (spare vacuum chamber) in which the atmosphere can be switched between an atmospheric atmosphere and a vacuum atmosphere; reference numeral 106 denotes a vacuum conveyance chamber in which there are two conveyance arms 107; reference numerals 108 and 109 denote the film deposition apparatuses according to the modes for carrying out the embodiments of the present invention. The conveyance container 101 is conveyed from the outside to a conveyance in/out port provided with a placing table not depicted, is then connected to the atmospheric conveyance chamber 102. After that a lid of the conveyance container 101 is opened by an opening/closing mechanism not depicted, and the conveyance arm 103 takes out a wafer W from the inside of the conveyance container 101. Next, the wafer W is conveyed into the load lock chamber 104 (105), the atmosphere in the load lock chamber is switched into a vacuum atmosphere, after that the wafer W is taken out by the conveyance arm 107, and is conveyed into the film deposition apparatus 108 or 109; and then, the above-mentioned film deposition process is carried out on the wafer W in the film deposition apparatus 108 or 109. By providing plural, for example, two film deposition apparatuses according to the mode for carrying out the embodiments of the present invention, for example, each processing five wafers W, for example, it is possible to carry out ALD (MLD) with high throughput.

### EMBODIMENT

### Simulation

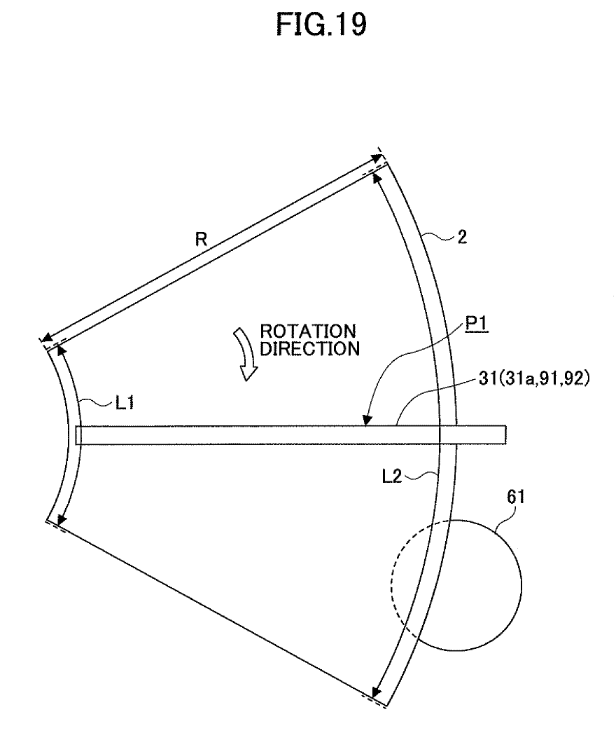

A turntable-type film deposition model was produced, reaction gas providing parts having various shapes were applied, and concentration distributions of provided gases were confirmed. As depicted in FIG. 19, the film deposition model was configured such that, for example, the first processing zone P1 depicted in FIG. 3 was included, and the turntable 2, the first reaction gas providing part and the first evacuation opening 61 were disposed in the sectorial space surrounded by the two projection parts 4. The first reaction gas providing part was disposed at the center in the circumferential direction of the sectorial space depicted in FIG. 19, and the evacuation opening 61 was disposed, with respect to the first reaction gas providing part, to the downstream side in the rotation direction of the turntable 2, at the periphery of and below the turntable 2. A size of a model space such as an inter-circumferential length L1, an outer circumferential length L2, and a radial length R of the sectorial space, a height of the ceiling surface 45 (second ceiling surface) not depicted in FIG. 19 from the top surface of the turntable 2, and so forth, was the same as that of the actual film deposition apparatus. Further, an amount of providing the BTBAS gas from each reaction gas providing part, amounts of the N₂ gas provided to the sectorial space from the upstream and downstream sides, the rotational speed of the turntable 2, a process pressure in the space and so forth were set in the parameter ranges mentioned above as the examples of the processing parameters.

A. Simulation Conditions

### Embodiment 1

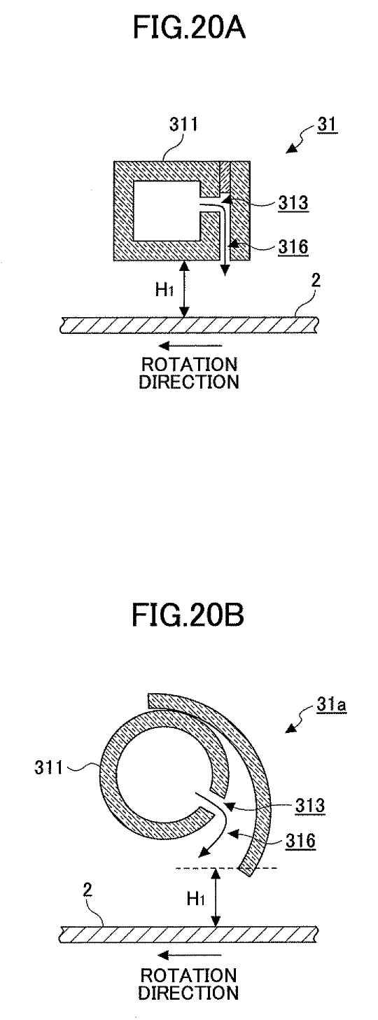

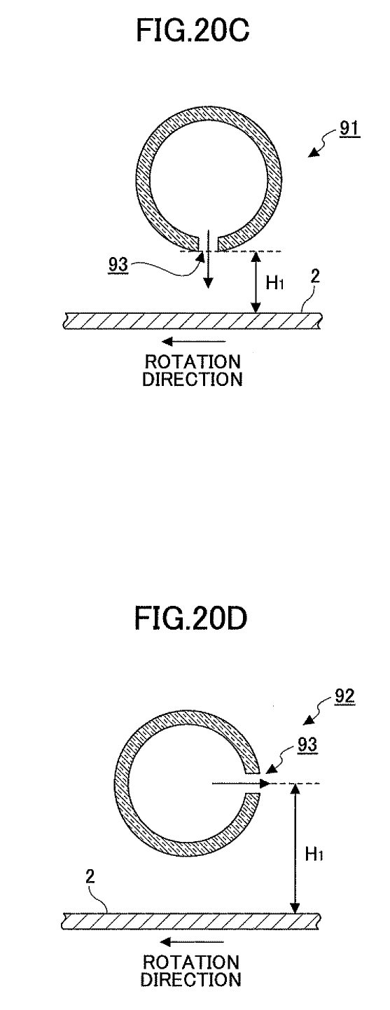

As the first reaction gas providing part, a gas injector 31 the same as that according to the mode for carrying out the embodiments of the present invention depicted in FIGS. 8-10B was provided, and a concentration distribution of the BTBAS gas just under the gas injector 31 was simulated. FIG. 20A diagrammatically depicts a vertical-section side view of the gas injector 31 used in the simulation. Design conditions of the gas injector 31 were as follows:

Diameter of gas outflow opening 313: 0.5 mm

Interval between centers of gas outflow openings 313: 5.0 mm

Disposed number of gas outflow openings 313: 67

Width of slit of gas discharge opening 316: 0.3 mm

Height H1 from top surface (surface of wafer W) of turntable 2 through gas discharge opening 316: 4 mm

### Embodiment 2

As the first reaction gas providing part, a gas injector 31a the same as that according to the other mode for carrying out the embodiments of the present invention depicted in FIGS. 12-13 was provided, and a concentration distribution of the BTBAS gas just under the gas injector 31a was simulated. FIG. 20B diagrammatically depicts a vertical-section side view of the gas injector 31a used in the simulation. Design conditions of the gas injector 31a were as follows:

Diameter of gas outflow opening 313: 0.5 mm

Interval between centers of gas outflow openings 313: 10 mm

Disposed number of gas outflow openings 313: 32

Width of slit of gas discharge opening 316 viewed from bottom: 2.0 mm

Height H1 from top surface (surface of wafer W) of turntable 2 through gas discharge opening 316: 4 mm

### Comparison Example 1

As the first reaction gas providing part, a reaction gas nozzle 91 depicted in FIG. 20C in the reference example was provided, and a concentration distribution of the BTBAS gas just under the reaction gas nozzle 91 was simulated. The reaction gas nozzle 91 was configured to be approximately the same as the reaction gas nozzle 32 described above with reference to FIGS. 2 and 3 for providing the O₃ gas, had a configuration such that gas outflow openings 93 were disposed along a longitudinal direction at intervals on a bottom surface of the cylindrical reaction gas nozzle 91. Design conditions of the reaction gas nozzle 91 were as follows:

Diameter of gas outflow opening 93: 0.5 mm

Interval between centers of gas outflow openings 93: 10 mm

Disposed number of gas outflow openings 93: 32

Height H1 from top surface (surface of wafer W) of turntable 2 through gas outflow openings 93: 4 mm

### Comparison Example 2

As the first reaction gas providing part, a reaction gas nozzle 92 depicted in FIG. 20D in the reference example was provided, and a concentration distribution of the BTBAS gas just under the reaction gas nozzle 92 was simulated. The reaction gas nozzle 92 in (comparison example 2) was different from the above-mentioned reaction gas nozzle 91 in (comparison example 1) in that the reaction gas nozzle 91 was rotated 90° counterclockwise viewed from the base end side, and thus, the gas outflow openings 93 faced onto the upstream side in the rotation direction of the turntable 2 as depicted in FIG. 20D. Design conditions of the reaction gas nozzle 92 were as follows:

Diameter of gas outflow opening 93: 0.5 mm

Interval between centers of gas outflow openings 93: 10 mm

Disposed number of gas outflow openings 93: 32

Height H1 from top surface (surface of wafer W) of turntable 2 through centers of gas outflow openings 93: 4 mm

B. Simulation Result

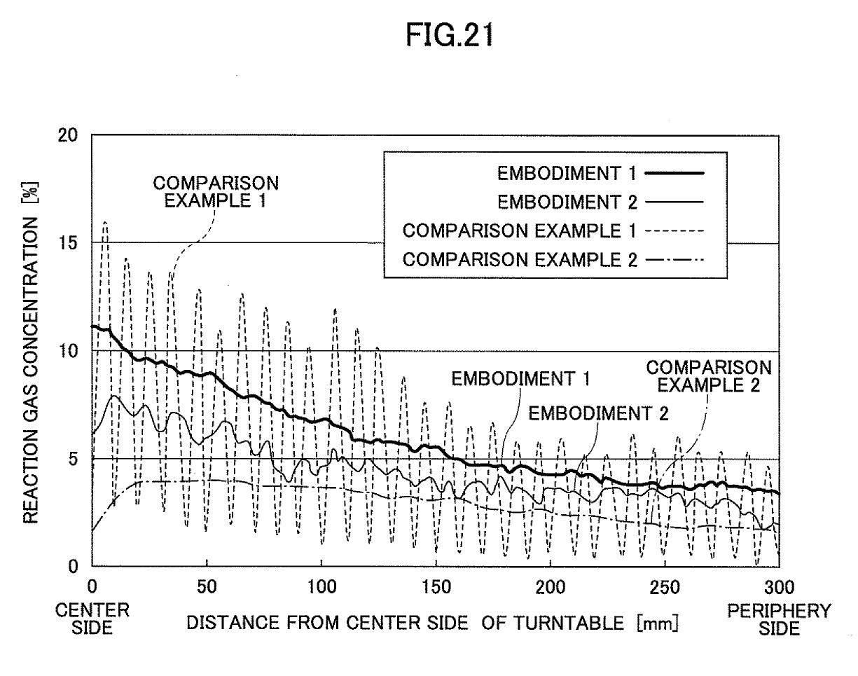

FIG. 21 depicts concentration distributions of the BTBAS gas in the respective embodiments and comparison examples. An abscissa axis of FIG. 21 depicts a distance [mm] from the center side of the turntable 2 in such a manner that a position of the wafer W of a diameter 300 mm passing below the above-mentioned reaction gas providing part (gas injector 31 or 31a, or the reaction gas nozzle 91 or 92) corresponding to the innermost end on the center side of the turntable 2 is indicated as 0 mm and a position corresponding to the outermost end on the periphery side of the turntable 2 is indicated as 300 mm. Further, an ordinate axis of FIG. 21 denotes a concentration [%] of the reaction gas (BTBAS) on the top surface of the turntable 2 just under each reaction gas providing part (gas injector 31 or 31a, or the reaction gas nozzle 91 or 92), i.e., on the surface of the wafer W. In FIG. 21, a result of (Embodiment 1) is indicated by a bold solid line, a result of (Embodiment 2) is indicated by a thin solid line, a result of (Comparison Example 1) is indicated by a broken line and a result of (Comparison Example 2) is indicated by a dashed line.

According to the result of (Embodiment 1) indicated by the bold solid line, such a large undulation phenomenon appearing in (Comparison Example 1) described below did not appear in the reaction gas concentration distribution provided to the surface of the wafer W. However, in the simulation result of (Embodiment 1), the reaction gas concentration provided to the surface of the wafer W gently decreased from the center side through the periphery side of the turntable 2, and results in an ever-decreasing trend line in FIG. 21. This is considered to be because, since the turntable 2 is rotated as a simulation condition, a moving distance per unit time of the turntable 2 is long on the periphery side of the quickly rotating turntable 2. As a result, the reaction gas is transported far during a short time, and the gas concentration is low. In contrast thereto, on the center side on the quick rotating turntable 2, a distance for which the reaction gas is transported is short in comparison to the periphery side, and the gas concentration is high.

Further, since, as depicted in FIG. 19, the first evacuation opening 61 is disposed at the outer circumferential position on the downside of the turntable 2, an influence of a force of ejecting the gas provided by the gas injector 31 being strong on the periphery side of the turntable 2 near to the evacuation opening 61, and the force of ejecting the gas being weak on the center side of the turntable 2 far from the evacuation opening 61 is also considered. Such a concentration distribution can be adjusted such that the concentration distribution becomes uniform between the center side and the periphery side of the turntable 2 as a result of, as depicted in FIGS. 10A and 10B, some of the gas outflow openings 313 being sealed by means of the seal 318 or such so that the intervals of disposing the gas outflow openings 313 are increased at an area at which the reaction gas concentration is high, or so. The phenomenon that the concentration distribution of the reaction gas provided to the surface of the wafer W is in an ever-decreasing manner in FIG. 21 is also observed in (Embodiment 2), (Comparison Example 1) and (Comparison Example 2). A cause thereof is considered the same as that described above for (Embodiment 1).

Further, according to the simulation result of (Embodiment 1), in comparison to (Embodiment 2) and (Comparison Example 2) described above, the concentration of the reaction gas provided to the surface of the wafer W is high throughout approximately all the area just under the gas injector 31. This is considered to be because, since, as described with reference to FIG. 8, for example, the reaction gas exiting the gas discharge opening 316 of the gas injector 31 is provided toward the wafer W approximately perpendicularly, the reaction gas is provided such that the reaction gas is not easily caused to fly upward by the N₂ gas flowing around, in comparison to (Embodiment 2) and (Comparison Example 2) in which the reaction gas is provided at an angle. In this point, the gas injector 31 according to (Embodiment 1) can provide the reaction gas efficiently to the surface of the wafer W even with such a relatively small amount of providing the reaction gas as, for example, 100 sccm, and it is possible to improve a film deposition rate in comparison to the other examples. It is noted that, (Comparison Example 1) in which the gas outflow openings 93 are formed downward perpendicularly cannot simply be compared with (Embodiment 1) for the easiness of the reaction gas being caused to fly upward by the N₂ gas flowing around. However, as described below, (Comparison Example 1) causes the undulation phenomenon of the reaction gas provided to the surface of the wafer W, and thus, it can be said that the gas injector 31 according to (Embodiment 1) is superior in a viewpoint of forming a film with a uniform film thickness.

Next, also according to the simulation result of (Embodiment 2) indicated by the thin solid line in FIG. 21, such a large undulation phenomenon appearing in (Comparison Example 1) described above did not appear in the reaction gas concentration distribution provided to the surface of the wafer W. On the other hand, in the reaction gas concentration distribution, such a phenomenon the same as that of (Embodiment 1) that the reaction gas concentration gently decreases in an ever-decreasing manner from the center side through the periphery side of the turntable 2 appeared. The phenomenon is considered to be because of, as discussed above for (Embodiment 1), a difference in a transportation distance per unit time of the turntable 2 between the center side and the periphery side, or a position of the evacuation opening 61, and it is possible to adjust the reaction gas concentration distribution to be uniform by increasing intervals of the gas outflow openings 313 by sealing some of the gas outflow openings 313 by means of the seals 318 or such, or so.

Further, the reaction gas concentration provided to the surface of the wafer W is lower than that of (Embodiment 1) and higher than (Comparison Example 2) throughout approximately all the area just under the gas injector 31a. This is considered to be because, as described above with reference to FIG. 12 for example, since the reaction gas is provided to the processing zone P1 with an oblique inclination to a direction in which the gas discharge opening 316 faces, a difference occurs from whether the reaction gas is easily caused to fly upward by a flow of the N₂ gas. Therefore, in comparison to (Embodiment 1) in which the reaction gas is provided perpendicularly, (Embodiment 2) is such that the reaction gas is easily caused to fly upward by the flow of the N₂ gas. In comparison to (Comparison Example 2) in which the reaction gas is provided laterally, (Embodiment 2) is such that the reaction gas is not easily caused to fly upward by the flow of the N₂ gas.

In comparison to the above-discussed respective embodiments, according to the simulation result of (Comparison Example 1) indicated by the broken line in FIG. 21, the undulation phenomenon is observed in which, the reaction gas concentration provided to the surface of the wafer W just under the reaction gas nozzle 91 changes significantly in a saw-tooth manner in the range of concentration from several % through ten and several % with respect to the abscissa axis of FIG. 21. In this concentration distribution, a position at which the reaction gas concentration has a local maximum corresponds to a position at which each gas outflow opening 93 is disposed on the reaction gas nozzle 91, which supports the idea that the reaction gas concentration distribution is such that the gas outflow openings 93 are easily reflected. Further, also in a result of an experiment that was carried out separately, it was observed that unevenness occurred corresponding to positions of disposing the gas outflow openings 93 in a film formed by using the gas outflow openings 93 the same as those of (Comparison Example 1).

Next, according to the simulation result of (Comparison Example 2) indicated by the dashed line, since the direction of blowing out the reaction gas is a lateral direction, the reaction gas concentration undulation phenomenon observed in (Comparison Example 1) is not observed. However, the reaction gas concentration provided to the surface of the wafer W in (Comparison Example 2) is lower than that of any one of (Embodiment 1) and (Embodiment 2). This is considered to be because, since the direction of blowing out the reaction gas is the lateral direction, the reaction gas is such that the reaction gas is most easily caused to fly upward by a flow of the N₂ gas, and, a method of providing the reaction gas according to (Comparison Example 2) can be deemed as being such that a film deposition rate is low in comparison to these embodiments,

From the result of thus studying, it can be deemed that, also as can be seen from the simulation results of (Embodiment 1) and (Embodiment 2), the gas injectors 31 and 31a according to the modes for carrying out the embodiments of the present invention in which the reaction gas discharged by the gas outflow openings 313 is made to hit the guide member 315 provided at a position to face toward the gas outflow openings 313, and then, is provided to the processing zone P1 can form a film having a uniform film thickness in comparison to the reaction gas nozzles 91 and 92 according to (Comparison Example 1) and (Comparison Example 2), and also, can improve a film deposition rate in comparison to (Comparison Example 2).

The present invention is not limited to the above-described embodiments, and variations and modifications may be made without departing from the scope of the invention.

What is claimed is:

1. A gas injector comprising:
an injector body having a gas inlet and a gas passage;
plural gas outflow openings disposed on a wall part of the injector body along a longitudinal direction of the injector body, and;
a guide member that provides a slit-shaped gas discharge opening extending in the longitudinal direction of the injector body on an outer surface of the injector body, and guides gas flowing from the gas outflow openings to the gas discharge opening.

2. The gas injector as claimed in claim 1 wherein:
the wall part of the injector body has a flat part that has the plural gas outflow openings, and the slit-shaped gas discharge opening is located at one edge of the flat part.

3. The gas injector as claimed in claim 2, wherein:
the guide member extends parallel to the flat part.

4. The gas injector as claimed in claim 2, wherein:
the injector body has a shape of a rectangular tube.

5. The gas injector as claimed in claim 1, wherein:
the injector body has a shape of a cylindrical tube, and a horizontal section of the guide member has an arc shape extending along an outer surface of the injector body.

6. A film deposition apparatus which forms a thin film of reaction products laminated on a surface of a substrate by repeating a cycle of providing to the surface of the substrate at least two reaction gases in sequence which react with each other in a vacuum chamber, the film deposition apparatus comprising:
a turntable in the vacuum chamber;
a substrate placing area on the turntable for placing the substrate;
a first reaction gas providing part that provides a first reaction gas to a side of the turntable on which the substrate placing area is provided and a second reaction gas providing part that provides a second reaction gas to the side of the turntable, the first and second reaction gas providing parts being apart from one another in a rotation direction of the turntable;
a separating zone that separates an atmosphere of a first processing zone for providing the first reaction gas and an atmosphere of a second processing zone for providing the second reaction gas, the separating zone being located between the first processing zone and the second processing zone in the rotation direction of the turntable, the separating zone having a separating gas providing part that provides a separating gas; and
an evacuation opening for evacuating the vacuum chamber, wherein:
at least one of the first and second reaction providing parts comprises the gas injector claimed in claim 1, the gas injector extends across the rotation direction of the turntable, and the gas discharge opening of the gas injector faces toward the turntable.

7. The film deposition apparatus as claimed in claim 6, further comprising:
a central zone at the center of the vacuum chamber that separates the atmosphere of the first processing zone and the atmosphere of the second processing zone and has a separating gas discharge opening that discharges the separating gas to the side of the turntable on which the substrate placing area is provided, wherein:
the evacuation opening discharges the separating gas that diffuses to both sides of the separating zone, the separating gas discharged from the central zone, and the first and second reaction gases.

8. The film deposition apparatus as claimed in claim 7, wherein:
the central zone is defined by a rotation center part of the turntable and a top surface of the vacuum chamber, and is purged by using the separating gas.

9. The film deposition apparatus as claimed in claim 7, wherein:
the central zone includes a support provided at a center of the vacuum chamber between the top surface and a bottom surface of the vacuum chamber, and includes a rotating sleeve that surrounds the support and is rotatable around a vertical shaft, and
the rotating sleeve acts as a rotating shaft of the turntable.

10. The film deposition apparatus as claimed in claim 6, wherein:
the separating zone is located at each of both sides in the rotating direction of the separating gas providing part, and has a ceiling surface that provides a narrow space above the turntable for flowing the separating gas in a direction extending from the separating zone to the first and second processing zones.

11. The film deposition apparatus as claimed in claim 6, wherein:
the evacuation opening evacuates the vacuum chamber via a gap between a circumferential edge of the turntable and an inner circumferential wall of the vacuum chamber.

12. The film deposition apparatus as claimed in claim 6, wherein:
the separating gas providing part has discharge openings disposed from one of the rotation center part and a circumferential edge of the turntable to the other.

13. The film deposition apparatus as claimed in claim 6, wherein:
plural of the evacuation openings are provided one at each side in the rotation direction of the separating zone and discharge the corresponding first and second reaction gases.

14. The film deposition apparatus as claimed in claim 6, wherein:
an edge side portion of the vacuum chamber at a ceiling surface of the separating zone is a part of an inner circumferential wall of the vacuum chamber that bends to face toward an outer edge surface of the turntable, and a space between the bending portion of the vacuum chamber at the ceiling surface and the outer edge surface of the turntable has a size to avoid infiltration of the first and second reaction gases.

15. The film deposition apparatus as claimed in claim 6, wherein:
a portion of the separating zone at a ceiling surface of the separating zone on an upstream side in the rotation direction of the turntable with respect to the separating gas providing part has a width in the rotation direction that is longer at a position nearer to the outer edge of the separating zone.
